(19) United States
(12) Patent Application Publication
(10) Pub. No.: US 2025/0148185 A1
(43) Pub. Date: May 8, 2025

(54) SYSTEM AND METHOD FOR AUTOMATIC EXTRACTION OF INTEGRATED CIRCUIT COMPONENT DATA

(71) Applicant: TECHINSIGHTS INC., Ottawa (CA)

(72) Inventors: Christopher PAWLOWICZ, Ottawa (CA); Michael GREEN, Nepean (CA); Alexei IOUDOVSKI, Ottawa (CA); Bruno MACHADO TRINDADE, Kanata (CA)

(21) Appl. No.: 18/837,085

(22) PCT Filed: Feb. 9, 2023
(86) PCT No.: PCT/CA2023/050171

§ 371 Date: Aug. 8, 2024

(30) Foreign Application Priority Data
Feb. 10, 2022 (CA) 3148567

(51) Int. Cl. G06F 30/398; G06T 7/00

(52) U.S. Cl. CPC G06F 30/398; G06T 7/0004; G06T 2207/10061

(57) ABSTRACT

Described are various embodiments of a system and method for automatic extraction of integrated circuit component data. In one embodiment, a method is provided for automatically extracting transistor data from a digital representation of an integrated circuit that comprises digitally defining at least one diffusion space corresponding to a respective spatial region of the IC that comprises at least one diffusion feature. For each discrete diffusion space, diffusion space circuit features that intersect with each diffusion feature are incrementally assessed by assigning a current state value to each diffusion space circuit feature based on an identified feature characteristic associated therewith and an identified feature characteristic of an electrically adjacent feature in the diffusion space.

### RELATED APPLICATION

The instant application is related to an claims the benefit of priority to Canadian Patent Application serial number 3,148,567, entitled “SYSTEM AND METHOD FOR AUTOMATIC EXTRACTION OF INTEGRATED CIRCUIT COMPONENT DATA” and filed Feb. 10, 2022, the content of which are herein fully incorporated by reference.

### FIELD OF THE DISCLOSURE

The present disclosure relates to reverse engineering, and, in particular, to a system and method for automatic extraction of integrated circuit component data.

### BACKGROUND

The extraction of circuit components of existing physical integrated circuits (ICs) has benefits in many applications, including reverse engineering (RE) and quality control. However, the sheer number of elements that must be processed to do so requires a level of automation that is challenging using conventional means, such as electron microscopy (EM) images.

U.S. Pat. No. 5,694,481 entitled “Automated Design Analysis System for Generating Circuit Schematics from High Magnification Images of an Integrated Circuit” and issued to Lam, et al. on Dec. 2, 1997 discloses an overview of a semi-automated IC RE process, including a method for generating schematic diagrams of an IC using EM images.

Other examples of disclosures related to IC component extraction include U.S. Pat. No. 5,086,477 entitled “Automated System for Extracting Design and Layout Information from an Integrated Circuit”, issued Feb. 4, 1994 to Yu and Berglund; U.S. Pat. No. 10,386,409 entitled “Non-Destructive Determination of Components of Integrated Circuits” and issued Aug. 20, 2019 to Gignac, et al.; and U.S. Pat. No. 10,515,183 entitled “Integrated Circuit Identification” and issued Dec. 24, 2019 to Shehata, et al. Such examples typically rely on template matching processes for component extraction, which can be challenging in view of the data acquisition methods, and the amount of user intervention and/or amount of computational processing required. These challenges related to automatic circuit feature extraction may be exacerbated for the extraction of transistor components.

This background information is provided to reveal information believed by the applicant to be of possible relevance. No admission is necessarily intended, nor should be construed, that any of the preceding information constitutes prior art or forms part of the general common knowledge in the relevant art.

### SUMMARY

The following presents a simplified summary of the general inventive concept(s) described herein to provide a basic understanding of some aspects of the disclosure. This summary is not an extensive overview of the disclosure. It is not intended to restrict key or critical elements of embodiments of the disclosure or to delineate their scope beyond that which is explicitly or implicitly described by the following description and claims.

A need exists for a system and method for automatic extraction of integrated circuit component data that overcome some of the drawbacks of known techniques, or at least, provides a useful alternative thereto. Some aspects of this disclosure provide examples of such systems and methods.

In accordance with one aspect, there is provided a method for automatically extracting transistor data from a digital representation comprising a feature dataset comprising a list of circuit features and spatial coordinates thereof of an integrated circuit (IC), the method automatically executed by at least one digital data processor operable to execute digital instructions for: defining at least one diffusion space corresponding to a respective spatial region of the IC comprising at least one diffusion feature, and, for each of the at least one discrete diffusion space, incrementally assessing diffusion space circuit features of the feature dataset that intersect with each of the at least one diffusion feature by assigning a current state value to each diffusion space circuit feature based on an identified current feature characteristic associated therewith and an identified feature characteristic of an electrically adjacent feature in the diffusion space.

In accordance with one aspect, there is provided a method for automatically extracting transistor data from a digital representation of at least a portion of an integrated circuit (IC), said digital representation comprising a feature dataset comprising at least one list of circuit features of the IC and, corresponding thereto, at least one of spatial coordinates thereof and connectivity to other circuit features, the method automatically executed by at least one digital data processor operable to execute digital instructions for: defining at least one diffusion space corresponding to respective spatial regions of the IC each comprising at least a portion of a diffusion feature; incrementally assessing diffusion space circuit features of the feature dataset that intersect with the at least one diffusion feature or portion thereof, by assigning a current state value to each diffusion space circuit feature based on an identified current feature characteristic associated therewith and an identified feature characteristic of an electrically adjacent feature in the corresponding diffusion space.

In one embodiment, the feature dataset comprises a plurality of circuit feature datasets, each circuit feature dataset corresponding to respective lists of circuit features and one or both of spatial coordinates thereof or connectivity, electrical or otherwise, with other circuit features.

In one embodiment, the incrementally assessing diffusion space circuit features comprises incrementally assessing the diffusion space circuit features in accordance with a designated spatial increment.

In one embodiment, the method further comprises partitioning the feature dataset into the diffusion space circuit features for each of the at least one discrete diffusion space.

In one embodiment, the incrementally assessing diffusion space circuit features comprises iterating a finite state machine for the assigning a current state value.

In one embodiment, the respective spatial region of the IC comprises a three-dimensional volume of the IC.

In one embodiment, the digital representation is derived from one or more images of the IC.

In one embodiment, the digital representation comprises one or more of pixel data, binary data, pixel data, polygon data, image data, greyscale image data, or image data.

In one embodiment, the digital representation is representative of one or more of a scanning electron microscopy (SEM) image, or a transmission electron microscopy (TEM) image.

In one embodiment, the digital representation is representative of a mosaicked image generated from a plurality tiled images acquired with a high magnification imager.

In one embodiment, the list of circuit features corresponds to one or more of a gate dataset, a polysilicon dataset, a contact dataset, a metal dataset, or a diffusion space dataset.

In one embodiment, the method is repeated for a plurality of IC layers of the IC.

In one embodiment, the method further comprises generating a netlist based at least in part on said current state value assigned for each of said diffusion space circuit features.

In one embodiment, the spatial coordinates of the circuit features relate to a spatial distribution of the circuit features.

In one embodiment, the spatial distribution corresponds to one or more of a respective characteristic position, a width, or a height of respective surface features.

In one embodiment, each of the at least one discrete diffusion space is assessed by a respective digital processing resource.

In one embodiment, the method further comprises partitioning the digital representation into a plurality of tile regions corresponding to respective spatial regions of the IC, wherein the at least one discrete diffusion space comprising at least one discrete diffusion feature is defined for each of the plurality of tile regions.

In one embodiment, partitioning the digital representation is automatically performed based on a distribution of circuit features.

In one embodiment, the method further comprises distinguishing, based at least in part on the spatial coordinates of the circuit features, between boundary circuit features and inner circuit features, wherein boundary circuit features comprise circuit features intersecting a boundary of at least one of the plurality of tile regions.

In one embodiment, the at least one discrete diffusion feature comprises an inner circuit feature.

In one embodiment, defining at least one diffusion space and incrementally assessing diffusion space circuit features, for at least two of the plurality of tile regions, are digitally executed in parallel by respective digital processing resources.

In one embodiment, assigning a current state value comprises assigning a value of corresponding to a transistor channel connection or a transistor gate.

In one embodiment, the transistor channel connection comprises a transistor source or a transistor drain or a transistor contact.

In one embodiment, assigning a current state value comprises assigning a virtual channel connection to a current diffusion space circuit feature based at least in part on an absence of a contact feature associated with the current diffusion space feature.

In accordance with another aspect, there is provided a non-transitory computer-readable medium comprising digital instructions to be implemented by one or more digital data processors to automatically extract transistor data from a digital representation comprising a feature dataset comprising a list of circuit features and spatial coordinates thereof of an integrated circuit (IC) by defining at least one diffusion space corresponding to a respective spatial region of the IC comprising at least one diffusion feature, and, for each of the at least one discrete diffusion space, incrementally assessing diffusion space circuit features of the feature dataset that intersect with each of the at least one diffusion feature by assigning a current state value to each diffusion space circuit feature based on an identified current feature characteristic associated therewith and an identified feature characteristic of an electrically adjacent feature in the diffusion space.

In accordance with another aspect, there is provided a non-transitory computer-readable medium comprising digital instructions to be implemented by one or more digital data processors to automatically extract transistor data from a digital representation of at least a portion of an integrated circuit (IC), said digital representation comprising a feature dataset comprising at least one list of circuit features of the IC and, corresponding thereto, at least one of spatial coordinates thereof and connectivity to other circuit features, by: defining at least one diffusion space corresponding to respective spatial regions of the IC each comprising at least a portion of a diffusion feature; incrementally assessing diffusion space circuit features of the feature dataset that intersect with the at least one diffusion feature or portion thereof by assigning a current state value to each diffusion space circuit feature based on an identified current feature characteristic associated therewith and an identified feature characteristic of an electrically adjacent feature in the corresponding diffusion space.

In one embodiment, the feature dataset comprises a plurality of circuit feature datasets, each circuit feature dataset corresponding to respective lists of circuit features and spatial coordinates thereof.

In one embodiment, incrementally assessing diffusion space circuit features comprises incrementally assessing the diffusion space circuit features in accordance with a designated spatial increment.

In one embodiment, the non-transitory computer-readable medium further comprises digital instructions for partitioning the feature dataset into the diffusion space circuit features for each of the at least one discrete diffusion space.

In one embodiment, the incrementally assessing diffusion space circuit features comprises iterating a finite state machine for the assigning a current state value.

In one embodiment, the respective spatial region of the IC comprises a three-dimensional volume of the IC.

In one embodiment, the digital representation is derived from one or more images of the IC.

In one embodiment, the digital representation comprises one or more of pixel data, binary data, pixel data, polygon data, image data, greyscale image data, or image data.

In one embodiment, the digital representation is representative of one or more of a scanning electron microscopy (SEM) image, or a transmission electron microscopy (TEM) image.

In one embodiment, the digital representation is representative of a mosaicked image generated from a plurality tiled images acquired with a high magnification imager.

In one embodiment, the list of circuit features corresponds to one or more of a gate dataset, a polysilicon dataset, a contact dataset, a metal dataset, or a diffusion space dataset.

In one embodiment, the digital instructions are repeatedly executable for a plurality of IC layers of the IC.

In one embodiment, the digital instructions are further executable to generate a netlist based at least in part on said current state value assigned for each of said diffusion space circuit features.

In one embodiment, the spatial coordinates of the circuit features relate to a spatial distribution of the circuit features.

In one embodiment, the spatial distribution corresponds to one or more of a respective characteristic position, a width, or a height of respective surface features.

In one embodiment, each of the at least one discrete diffusion space is assessed by a respective digital data processor.

In one embodiment, the non-transitory computer-readable medium further comprises digital instructions for partitioning the digital representation into a plurality of tile regions corresponding to respective spatial regions of the IC, wherein the at least one discrete diffusion space comprising at least one discrete diffusion feature is defined for each of the plurality of tile regions.

In one embodiment, partitioning the digital representation is automatically performed based on a distribution of circuit features.

In one embodiment, the non-transitory computer-readable medium further comprises digital instructions for distinguishing, based at least in part on the spatial coordinates of the circuit features, between boundary circuit features and inner circuit features, wherein boundary circuit features comprise circuit features intersecting a boundary of at least one of the plurality of tile regions.

In one embodiment, the at least one discrete diffusion feature comprises an inner circuit feature.

In one embodiment, defining at least one diffusion space and incrementally assessing diffusion space circuit features, for at least two of the plurality of tile regions, are digitally executed in parallel by respective digital processing resources.

In one embodiment, assigning a current state value comprises assigning a value of corresponding to a transistor channel connection or a transistor gate.

In one embodiment, the transistor channel connection comprises a transistor source or a transistor drain or a transistor contact.

In one embodiment, assigning a current state value comprises assigning a virtual channel connection to a current diffusion space circuit feature based at least in part on an absence of a contact feature associated with the current diffusion space feature.

In accordance with another aspect, there is provided a system for automatically extracting transistor data from a digital representation comprising a feature dataset comprising a list of circuit features and spatial coordinates thereof of an integrated circuit (IC), the system comprising a digital data storage device having stored thereon the digital representation, and at least one digital data processor operable to execute digital instructions for receiving as input the digital representation, defining from the digital representation at least one diffusion space corresponding to a respective spatial region of the IC comprising at least one diffusion feature, and for each of the at least one discrete diffusion space, incrementally assessing diffusion space circuit features of the feature dataset that intersect with each of the at least one diffusion feature by assigning a current state value to each diffusion space circuit feature based on an identified current feature characteristic associated therewith and an identified feature characteristic of an electrically adjacent feature in the diffusion space.

In accordance with another aspect, there is provided a system for automatically extracting transistor data from a digital representation of at least a portion of an integrated circuit (IC), said digital representation comprising a feature dataset comprising at least one list of circuit features of the IC and, corresponding thereto, at least one of spatial coordinates thereof and connectivity to other circuit features, the system comprising: a digital data storage device having stored thereon the digital representation; at least one digital data processor operable to execute digital instructions for: receiving as input the digital representation; defining from the digital representation at least one diffusion space corresponding to respective spatial regions of the IC each comprising at least a portion of a diffusion feature; incrementally assessing diffusion space circuit features of the feature dataset that intersect with the at least one diffusion feature or portion thereof by assigning a current state value to each diffusion space circuit feature based on an identified current feature characteristic associated therewith and an identified feature characteristic of an electrically adjacent feature in the corresponding diffusion space.

In one embodiment, the system further comprises a high magnification imager operable to acquire an image of the IC, and wherein the digital representation of the IC is representative of the image.

In one embodiment, the high magnification imager comprises an electron microscope.

In one embodiment, each of the at least one discrete diffusion space is assessed by a respective digital processing resource.

In one embodiment, the digital instructions further comprise instructions for partitioning the digital representation into a plurality of tile regions corresponding to respective spatial regions of the IC, wherein the at least one discrete diffusion space comprising at least one discrete diffusion feature is defined for each of the plurality of tile regions.

In one embodiment, the defining at least one diffusion space and the incrementally assessing diffusion space circuit features, for at least two of the plurality of tile regions, are digitally executed in parallel by respective digital processing resources.

Other aspects, features and/or advantages will become more apparent upon reading of the following non-restrictive description of specific embodiments thereof, given by way of example only with reference to the accompanying drawings.

### BRIEF DESCRIPTION OF THE FIGURES

Several embodiments of the present disclosure will be provided, by way of examples only, with reference to the appended drawings, wherein:

FIG. 1A is a diagram of an exemplary process for automatically extracting transistor data from a digital representation of an integrated circuit, in accordance with one embodiment, and FIG. 1B is a diagram of exemplary pre-processing steps related to the preparation of a digital representation for automatic extraction of circuit components, in accordance with one embodiment;

FIGS. 2A and 2B are schematics of exemplary digital representation of circuit features, in accordance with one embodiment;

FIG. 3 is a schematic of overlaid digital representations of circuit features, in accordance with one embodiment;

FIG. 4 is a schematic of exemplary diffusion space features, in accordance with one embodiment;

FIG. 5 is a schematic of an exemplary iterative assessment process for extracting features from a digital representation, in accordance with one embodiment; and

FIG. 6 is a schematic of exemplary extracted circuit feature data, in accordance with one embodiment.

Elements in the several figures are illustrated for simplicity and clarity and have not necessarily been drawn to scale. For example, the dimensions of some of the elements in the figures may be emphasized relative to other elements for facilitating understanding of the various presently disclosed embodiments. Also, common, but well-understood elements that are useful or necessary in commercially feasible embodiments are often not depicted in order to facilitate a less obstructed view of these various embodiments of the present disclosure.

### DETAILED DESCRIPTION

Various implementations and aspects of the specification will be described with reference to details discussed below. The following description and drawings are illustrative of the specification and are not to be construed as limiting the specification. Numerous specific details are described to provide a thorough understanding of various implementations of the present specification. However, in certain instances, well-known or conventional details are not described in order to provide a concise discussion of implementations of the present specification.

Various apparatuses and processes will be described below to provide examples of implementations of the system disclosed herein. No implementation described below limits any claimed implementation and any claimed implementations may cover processes or apparatuses that differ from those described below. The claimed implementations are not limited to apparatuses or processes having all of the features of any one apparatus or process described below or to features common to multiple or all of the apparatuses or processes described below. It is possible that an apparatus or process described below is not an implementation of any claimed subject matter.

Furthermore, numerous specific details are set forth in order to provide a thorough understanding of the implementations described herein. However, it will be understood by those skilled in the relevant arts that the implementations described herein may be practiced without these specific details. In other instances, well-known methods, procedures and components have not been described in detail so as not to obscure the implementations described herein.

In this specification, elements may be described as “configured to” perform one or more functions or “configured for” such functions. In general, an element that is configured to perform or configured for performing a function is enabled to perform the function, or is suitable for performing the function, or is adapted to perform the function, or is operable to perform the function, or is otherwise capable of performing the function.

It is understood that for the purpose of this specification, language of “at least one of X, Y, and Z” and “one or more of X, Y and Z” may be construed as X only, Y only, Z only, or any combination of two or more items X, Y, and Z (e.g., XYZ, XY, YZ, ZZ, and the like). Similar logic may be applied for two or more items in any occurrence of “at least one . . . ” and “one or more . . . ” language.

Unless defined otherwise, all technical and scientific terms used herein have the same meaning as commonly understood by one of ordinary skill in the art to which this invention belongs.

Throughout the specification and claims, the following terms take the meanings explicitly associated herein, unless the context clearly dictates otherwise. The phrase “in one of the embodiments” or “in at least one of the various embodiments” as used herein does not necessarily refer to the same embodiment, though it may. Furthermore, the phrase “in another embodiment” or “in some embodiments” as used herein does not necessarily refer to a different embodiment, although it may. Thus, as described below, various embodiments may be readily combined, without departing from the scope or spirit of the innovations disclosed herein.

In addition, as used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

The term “comprising” as used herein will be understood to mean that the list following is non-exhaustive and may or may not include any other additional suitable items, for example one or more further feature(s), component(s) and/or element(s) as appropriate.

Reverse engineering (RE) is now a common practice in the electronics industry with wide ranging applications, including quality control, the dissemination of concepts and techniques used in semiconductor chip manufacture, and intellectual property considerations with respect to assessing infringement and supporting patent licensing activities.

However, with ever-increasing integration levels of semiconductor circuits, RE has become increasingly specialised. For instance, many RE applications often require advanced microscopy systems operable to acquire thousands of images of integrated circuits (ICs) with sufficient resolution to visualise billions of micron and sub-micron features. The sheer number of elements that must be processed demands a level of automation that is challenging, particularly in view of the oft-required need of determining connectivity between circuit elements that are not necessarily logically placed within a circuit layer, but rather disposed to optimise use of space.

Various approaches for automatically analysing ICs have been proposed. One method is described in U.S. Pat. No. 5,694,481 entitled “Automated Design Analysis System for Generating Circuit Schematics from High Magnification Images of an Integrated Circuit” and issued to Lam, et al. on Dec. 2, 1997. This example, which illustrates an overview of the IC RE process in general, discloses a method for generating schematic diagrams of an IC using electron microscopy images. Due to the high resolution required to image circuit features, each layer of an IC layer is imaged by scanning many (tens to millions of) subregions independently, wherein such “tile” images are then mosaicked to generate a more complete 2D representation of the IC. These 2D mosaics are then aligned in a third dimension to establish a database from which schematics of the IC layout are generated.

With respect to the actual extraction of circuit features, however, such automatic processes may be challenged by many factors, not the least of which relate to the nature of the imaging techniques required to visualise such small components. For instance, the relatively widely used processes of scanning electron microscopy (SEM), transmission electron microscopy (TEM), scanning capacitance microscopy (SCM), scanning transmission electron microscopy (STEM), or the like, may produce images with an undesirable amount of noise and/or distortion. While these challenges are manageable for some applications when a circuit layout is already known (e.g. IC layout assessment for compliance with design rules), it is much more challenging to extract circuit features from imperfect data in an automated fashion when there is no available information about the intended circuit design.

The automated extraction of transistor information often presents further challenges. For instance, U.S. Pat. No. 5,086,477 entitled “Automated System for Extracting Design and Layout Information from an Integrated Circuit”, issued Feb. 4, 1994 to Yu and Berglund, discloses the identification of circuit components based on a comparison of circuit features with feature templates, or feature template libraries. However, such libraries of reference structures are incrementally built for each unique component and/or configuration. In view of how the components of even a single transistor (i.e. a source, gate, and drain), or a logic gate (e.g. OR, NAND, XNOR, or the like) may have a wide range of configurations and/or shapes for performing the same function, this approach may be practically very challenging, often resulting in template matching systems requiring a significant amount of operator intervention, being computationally very expensive, and being limited to specific component configurations (i.e. lacking robustness).

For instance, a NAND gate may comprise a designated number and connectivity transistors in series and in parallel. However, the specific configuration and placement of transistor features (e.g. the size, shape, and/or relative orientation of a source, gate, and drain for a transistor), and the configuration of the different transistors of the NAND gate, may vary even between even adjacent gates in an IC layer. An operator would therefore need to identify each transistor geometry present in each gate for inclusion into a template library, wherein automatic extraction of subsequent transistor components may only be successful only if a previously noted geometry is repeated.

Despite these deficiencies, this approach remains common in IC RE practice. For example, U.S. Pat. No. 10,386,409 entitled “Non-Destructive Determination of Components of Integrated Circuits” and issued Aug. 20, 2019 to Gignac, et al., and U.S. Pat. No. 10,515,183 entitled “Integrated Circuit Identification” and issued Dec. 24, 2019 to Shehata, et al., both disclose the identification of circuit elements based on pattern matching processes.

A need therefore exists for a system and process that overcomes the shortcomings of existing techniques of extracting IC component data, and particularly as such data pertains to transistor elements (e.g. data related to a transistor source, gate, or drain, positional data related thereto, or the like). Accordingly, the systems and methods described herein provide, in accordance with different embodiments, different examples in which transistor data may be automatically extracted from a digital representation an integrated circuit (IC) in a robust manner. Such examples, in accordance with different embodiments, may be useful in, for instance, reverse engineering applications, and may offer improved robustness and automation over existing approaches to IC component extraction.

It will be appreciated that, in accordance with various embodiments, a system or method for automatically extracting transistor data from a digital representation of an integrated circuit (IC) may relate to the use of one or more digital data processors operable to execute digital instructions for processing the digital representation. As will be further described below, this may comprise, in accordance with some embodiments, identifying one or more discrete diffusion spaces corresponding to respective spatial regions of the IC comprising at least one diffusion feature, and for each diffusion space (e.g. diffusion area or volume), incrementally assessing diffusion space circuit features that correspond to that diffusion feature, whether or not the assessment occurs diffusion region by diffusion region. Such assessments may further relate to assigning state values (e.g. 1s and 0s, state values corresponding to sources, gates, or drains, or the like) to each diffusion space circuit feature assessed based on an identified feature characteristic associated therewith (e.g. a contact, a polysilicon feature, a diffusion space feature, or the like), and a feature characteristic of an electrically adjacent feature. In some embodiments, identification of a diffusion spatial region may be done automatically by identifying the boundaries of such spatial region, by specifying a given set of circuit features as being associated with a diffusion spatial region by a user, by inferring an association with a particular spatial region for one or more circuit features based on shared characteristics with other circuit features, or a combination thereof.

In some embodiments, the foregoing incremental assessment for each diffusion space may be implemented across one or more subsets of the circuit feature dataset. Each incrementally assessed feature may be assessed in an order that is independent of its spatial inclusion in a given diffusion space, electrical adjacency, or any other spatial characteristic. For example, once the circuit features are represented in a circuit feature dataset based on image data analysis, the order in which each circuit feature is assessed to determine its relationship and characteristics as part of a transistor may not be material. In other words, once the analysis of all circuit features of a particular transistor are assessed directly from a circuit feature dataset (or one or more subsets thereof), the existence and characteristics of that transistor can be identified and there is no need for each circuit element thereof to be assessed in any particular sequence.

To this end, and in accordance with some embodiments, a digital representation of an IC may correspond to one or more high magnification images of an IC layer, or a portion of an IC layer. For example, and without limitation, a high magnification image may be acquired via an electron microscopy process (e.g. SEM, TEM, STEM, or the like). A digital representation may therefore, in accordance with some embodiments, comprise pixel values acquired from an SEM imaging process. Additionally, or alternatively, a digital representation may comprise processed pixel data from such images. For example, a digital representation of an IC may comprise segmented image data and/or a polygon representation of an IC layer portion generated upon conversion from pixelated format. In accordance with yet other embodiments, a digital representation of an IC layer may comprise a different form of binary representation, a greyscale image, an optical image of an IC layer portion, or the like. It will further be appreciated that a digital representation of an IC layer may comprise a set of previously extracted or generated circuit features or characterisations thereof, a non-limiting example of which may include a geometrical database standard for information interchange (GDSII) digital file format.

Accordingly, while various embodiments of the following description relate to the processing of polygon-based digital data representations of an IC circuit, it will be appreciated that the systems and methods herein described may additionally or alternatively relate to the processing of other forms of digital data representative of an IC circuit. For instance, a digital representation of an IC circuit may comprise a combination of data structures from which circuit component data may be extracted. For example, one embodiment relates to the extraction of circuit component information from pixelated or polygon-based image data cross-referenced and/or selected from a list of circuit features (or a plurality of lists of respective circuit features) generated from previously processed and/or filtered high magnification images.

In accordance with some embodiments, a digital representation may correspond to a high magnification image of an IC circuit acquired in accordance with a mosaicking process (e.g. as an image tile to be stitched with other tile images). Conversely, in accordance with other embodiments, a digital representation may comprise processed data corresponding to a region of an IC and that is extracted from or representative of an existing representation of a mosaicked image. For example, a digital representation may comprise processed data (e.g. polygons, segmented image data, or the like) corresponding to an area of interest (AOI) of a previously mosaicked IC layer image, wherein the AOI may be designated in accordance with various criteria. For example, one embodiment relates to the selection of an AOI for processing by an engineer, wherein the selection of an IC region is performed via a graphical user interface (GUI). In accordance with other embodiments, an AOI may be automatically selected based on, for instance, a density and/or type of features automatically identified in digital representation of an IC, or a portion thereof.

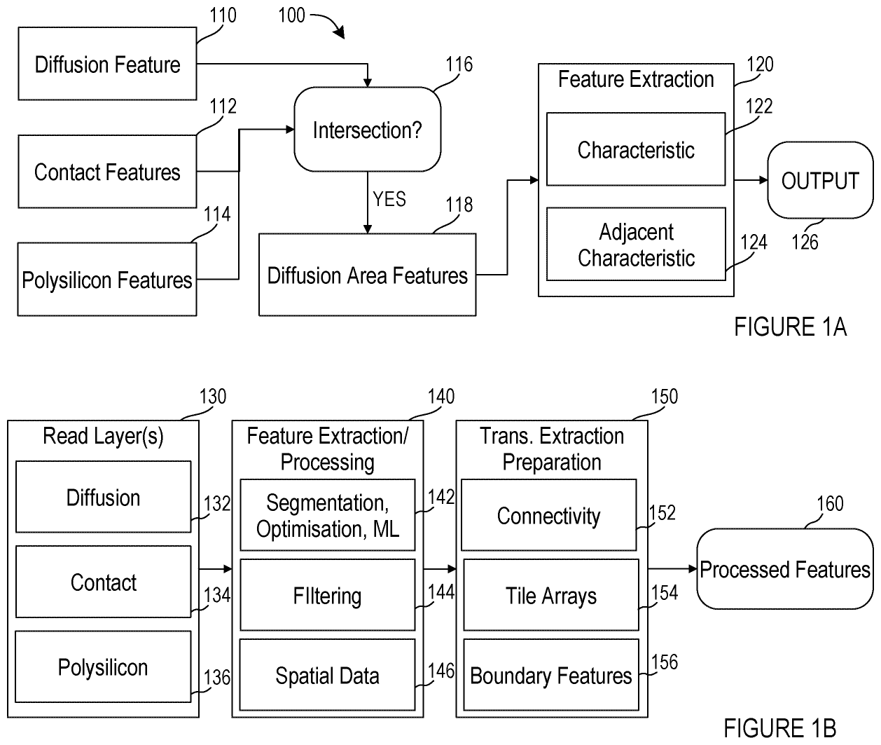

With reference to FIGS. 1A and 1B, and in accordance with one exemplary embodiment, a method for extracting transistor data, generally referred to using the numeral 100, will now be described. In this exemplary embodiment, FIG. 1A generally describes an extraction method 100 in which IC circuit features, including diffusion features 110, contact features 112 (also herein referred to as ‘contacts’ 112), and polysilicon features 114 are readily available as a digital representation of an IC circuit, an IC layer, or a portion thereof. However, for completeness, FIG. 1B shows further exemplary process steps that may be executed prior to transistor data extraction 100 to produce a digital representation of extracted features, in accordance with some embodiments. It will therefore be appreciated that depending on the application at hand, the quality of a digital representation, or the like, one or more of the process steps of FIGS. 1A and 1B may be optional and/or employed as needed (e.g. performed at different stages of the extraction process 100).

For instance, the exemplary extraction process 100 may first begin the acquisition 130 of one or more pixelated high magnification images (e.g. electron microscopy images), or ‘bundles’ of images, of one or more layers of an IC. Such images may correspond to, for instance, different physical and/or functional layers of the IC that are exposed in a delayering process. That is, while an IC may generally comprise what are commonly referred to as different ‘metal’ layers (e.g. metal 1, metal 2 . . . metal n), metal layers may in turn comprise different functional layers that comprise, for instance, respective transistor features. Accordingly, it will be appreciated that a first process step related to acquiring or reading an image layer(s) 130 may comprise acquiring a single image, more than one image, a bundle of images, or digital representations thereof, that in turn comprise data related to different materials and/or features, non-limiting examples of which may include diffusion features 132, contacts 134, and/or polysilicon features 136.

For example, and without limitation, a bundle of two image layers may be read 130 from an IC, wherein a first of the two layers comprises unprocessed data related diffusion features 132, while the second image may comprise data related to both contact 134 and polysilicon features 136. In this example, it will be understood that the two images may correspond to different physical layers exposed during, for instance, a delayering process, or may comprise two different images of the same physical layer, or a digital representation thereof.

It will be appreciated that various digital representations of such layer images may be output after reading 130. For instance, respective digital representations corresponding to respective diffusion layers 132, contact layers 134, and/or polysilicon layers 136 may be output as a binary representation for further processing, in accordance with one embodiment. In another embodiment, a single digital representation may be output, wherein pixel data corresponding to different respective layers (e.g. diffusion layers 132, contact layers 134, and polysilicon layers 136) may, for instance, be tagged with a corresponding identifier.

In some embodiments, information relating to diffusion region characteristics, including but not limited to the existence of a diffusion region, the spatial dimensions thereof, or association thereof with circuit features, may be determined by image analysis (e.g. operator identification from an image, or automated object recognition based on image data) and/or inference of such diffusion region characteristics based on an analysis of information or data collected in association with surrounding features (including but not limited to circuit features). For example, in some cases data analysis may identify specific circuit features that appear to closely align with transistor-related circuitry but either no image data exists, or incorrect image data analysis has occurred, and the existence of diffusion material can be inferred from the structure and connectivity of the other identified features. Indeed, characteristics about circuit features may be inferred based on related characteristics, such as but not limited to connectivity with other circuit features, spatial and connective relationships with other diffusion and/or circuit features, among other factors.

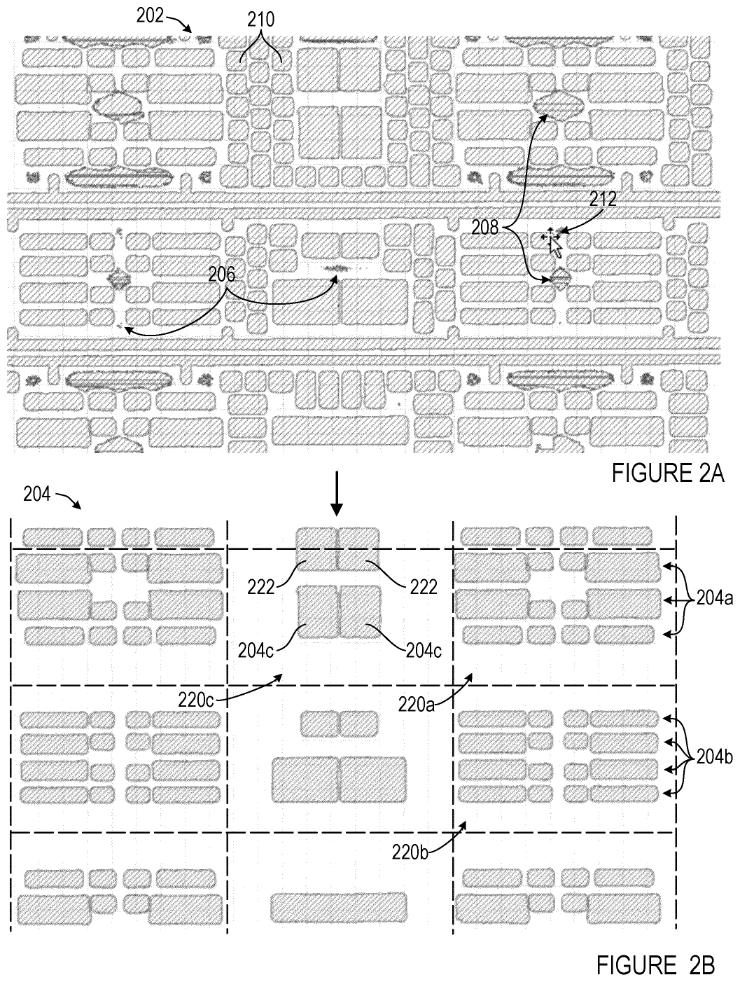

Upon reading layer data 130, if features therein were not automatically identified, a digital representation of circuit feature data may then be passed to or read by a digital layer extraction process 140. In such a process step, the digital representation of feature data may be processed to extract features in accordance with, for instance, a segmentation process 142. For instance, FIG. 2A schematically illustrates the results of an exemplary segmentation process 142, wherein an SEM image of an IC layer was segmented to generate a digital representation of segmented diffusion features 202. However, it will be appreciated that other processes known in the art for classifying features from images and/or digital representations thereof may be employed, in accordance with different embodiments. For example, one embodiment relates to the computation of a solution to optimisation problem 142 to extract features from, for instance, electron microscopy images. Yet other embodiments relate to the extraction of features using machine learning (ML) and/or image recognition processes 142.

Based on, for instance, a quality of original layer images 130, the quality of a feature extraction process 142, or the like, a digital representation may be further processed 140 in, for instance, a digital filtering step 144. For instance, FIG. 2B schematically shows filtered diffusion features 204 that remained in a digital representation of diffusion features (or were copied to a digital representation of filtered diffusion features 204) upon an exemplary filtration process 144 applied to the digital representation of segmented diffusion features 202 of FIG. 2A.

In accordance with various embodiments, a filtering process 144 may comprise, for instance, a size exclusion filter to remove features below a designated size (e.g. area, volume, or the like). For example, the diffusion features 206 of FIG. 2A were excluded from the digital representation of diffusion features in FIG. 2B, as they were below a threshold of minimum feature size for future processing. Such a size exclusion filter may be useful to, for instance, remove small features generated during a segmentation process 142 as a result of noise in an electron microscopy image.

In accordance with some embodiments, a digital filter may further comprise a “solidity” filter, wherein features with ‘noisy’ contours, or irregular non-diffusion feature-like aspects, may be excluded from further processing. For example, diffusion features 208 of FIG. 2A were excluded during the filtration process 144, as they were characterised as having a small area compared to the area of a rectangle or box bounding each respective feature. While it will be appreciated that various metrics may be applied in such a filter, in accordance with different embodiments, the embodiment of FIGS. 2A and 2B relates to a solidity filter excluding features having a ratio of a feature area to a corresponding bounding box area below 0.7.

In accordance with some embodiments, a filtering process 144 may further comprise one or more logical processes. For instance, as an individual transistor may be generally understood as comprising one or more of each of a source, gate, and drain, a filtering process 144 may comprise a logical filter in which an identified diffusion area 202 that does not comprise a contact, a polysilicon feature (e.g. a gate), or a connection thereto may be excluded from further processing. For example, the diffusion features 210 extracted from a segmentation process in FIG. 2A are not present in the digital representation of filtered diffusion features 204. Such features may, in accordance with some embodiments, be excluded from a filtered digital representation 204 for further processed due to a lack of contact or polysilicon layer (or lack of connectivity thereto) associated therewith.

It will be appreciated that while various embodiments relate to the automatic filtering 144 of IC layer features, as described above, some embodiments comprising a filtering process 144 may relate to a manual selection of layer features for filtering 144 based on one or more designated criteria. For instance, in accordance with some embodiments, an operator may manually select features in a digital representation of an IC layer via a graphical user interface (GUI) for examination and/or filtering 144, as indicated by the mouse cursor 212 in FIG. 2A.

It will further be appreciated that the filters described above are presented for illustrative purposes only, and that various other filtering processes 144 may be applied to a digital representation of IC features, in accordance with various embodiments. However, in the exemplary embodiment of FIGS. 2A and 2B, filtered diffusion features 204 are those segmented features 202 that were above a designated minimum feature size, comprised a solidity greater than 0.7 (i.e. a ratio of the feature area to a corresponding bounding box>0.7), and comprised an intersection with a polysilicon feature and at least one contact.

With reference again to FIG. 1, a feature extraction process 140 may, in accordance with some embodiments, further comprise the extraction of spatial and/or connectivity data 146, such as the position and/or relative position of extracted features (e.g. the 2D or 3D position of segmented features relative to other features of the same or a different layer). Spatial data 146 may, in accordance with some embodiments, be inherently preserved from, for instance, an imaging process in which IC layers are read 130. For example, SEM imaging of an IC circuit may inherently comprise spatial data of circuit features, as the pixels of a resultant image may naturally correspond or relate to positions on the IC surface. Such information may be preserved throughout, for instance, various segmentation processes 142 used to extract features from such images, or throughout any filtering processes 144 applied to a digital representation of circuit features. In accordance with other embodiments, spatial data 146 may be determined after layer reading 130. For instance, the relative positions of features in an image or digital representation, or between a plurality thereof, may be determined using one or more points of reference (e.g. a contact or other feature common to two or more images or layers, an orientation feature disposed on/in a plurality of layers, or the like). In accordance with other embodiments, spatial data 146 may be inherent in digital representations of IC circuit features, such as those generated using an electronic design automation (EDA) tool, or stored in a netlist format.

It will be appreciated that spatial data 146 may, in some embodiments, comprise a characteristic point position, and/or a spatial distribution in 2D or 3D of an extracted feature. For example, a rectangular feature (e.g. a diffusion layer feature) may be characterised by a point corresponding to a corner thereof (e.g. lower left corner), and be further characterised by a length and width of its rectangular geometry (and optionally a depth), such that the feature is characterised as a region (e.g. an area or a volume) of the IC. In accordance with other embodiments, a feature may be characterised as an array of pixel values, wherein array elements correspond to a physical position of the IC. For example, a 2D area of an IC may be characterised by a 2D array of values, wherein each array element is associated with or corresponds to position on an IC surface layer. As described above, spatial data 146 may be inherent in a digital representation of an IC layer. However, it will be appreciated that spatial data 146 may be established, for instance, upon segmenting 142 an image, and/or after a filtering 144 of a digital representation.

Such spatial data may further be processed to determine a connectivity 152 between components. That is, prior to transistor data extraction, a pre-processing step may comprise establishing cross-references among polygons of any or all layers of an IC, or digital representation thereof. While the exemplary embodiment of FIG. 1B schematically illustrates such a process step as being associated with an extraction preparation process 150, it will be appreciated that establishment of connectivity 152 between features may be performed in accordance with, for instance, a feature extraction process 140. In some embodiments, and without limitation, a connectivity 152 may be determined by an overlap in spatial coordinates associated with two or more IC features. For example, a contact feature may be spatially disposed such that it intersects with a polysilicon layer feature (i.e. respective digital representations of contact and polysilicon layer features may share one or more spatial coordinates 142, pixel regions, or voxels). Such an overlap or intersection may, in accordance with some embodiments, be interpreted as a connectivity between features.

Extracted features and/or spatial coordinates thereof may further be recorded for future reference (e.g. recorded in a netlist). For example, extracted features may be recorded in a ‘flat’ netlist as data associated with a feature type, spatial distribution, and/or connectivity to other extracted features. It will be appreciated that various embodiments may relate to the determination of a connectivity 152 between features of the same layer, or of different layers. That is, various embodiments may relate to the establishment of a connectivity 152 between features, whether the features correspond to different physical layers (e.g. metal 1, metal n, a diffusion feature layer, a contact and/or polysilicon layer, or the like), or to like or different features of the same physical layer.

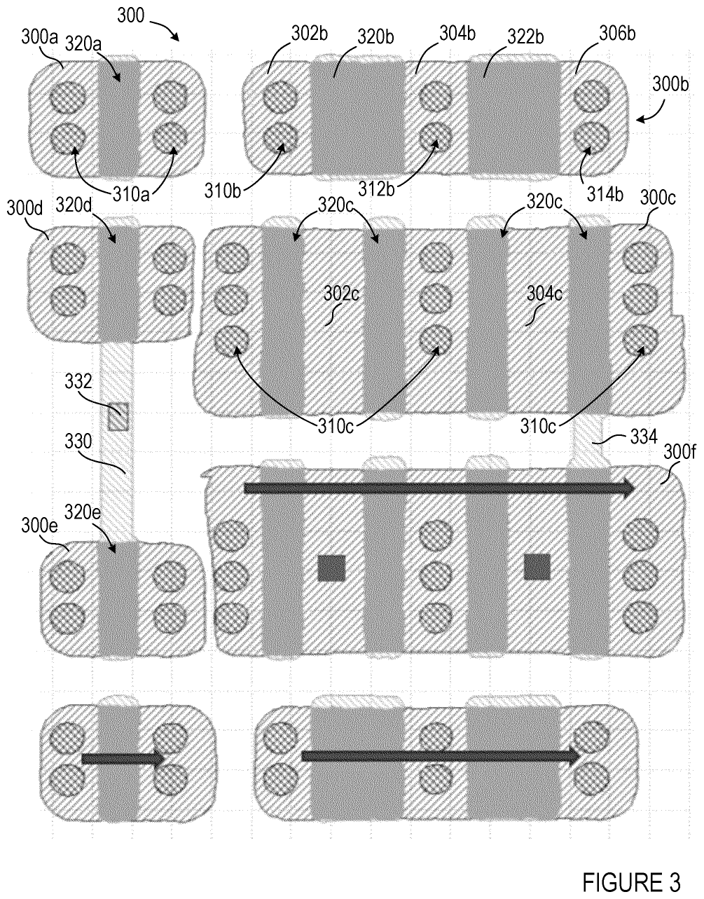

In accordance with various embodiments, FIG. 3 schematically illustrates how such connectivity 152 between features in a digital representation may be established based on the spatial data 144 of various extracted features. In this exemplary embodiment, eight (8) diffusion features 300 are schematically shown in accordance with their respective spatial coordinates 146, as they were determined upon SEM imaging of an AOI of an IC and preserved throughout a feature extraction process 140. The digital representation of FIG. 3 also schematically shows contact and polysilicon features overlaid on the diffusion features 300 in accordance with their respective spatial coordinates. For example, the diffusion feature 300a has overlaid thereon a digital representation of two arrays of contact features 310a, wherein each array is disposed at a different end of the diffusion feature 300a, and wherein the contact arrays 310a are separated on the diffusion feature 300a by a polysilicon feature 320a. An overlap of these spatial coordinates (e.g. the overlap or intersection of the contact features 310a with the spatial coordinates of the diffusion feature 300a, and the intersection of the spatial coordinates of the polysilicon layer 320a with the diffusion feature 300a) may, in accordance with some embodiments, be indicative of a connectivity between features. This example is accordingly representative of a relatively simple transistor configuration, wherein the ‘diffusion space’ of the IC (e.g. the region comprising an overlap of a diffusion feature 300a, contacts 310a, and the polysilicon feature 320a) comprises, from left to right (or from right to left), a contact (i.e. a source), a polysilicon feature (i.e. a gate), and another contact (i.e. a drain). It will be appreciated that while various embodiments herein described relate to a ‘diffusion area’ (e.g. a 2D space), various other embodiments relate to digital representations of different geometries, including 3- or other dimensionalities. Accordingly, a diffusion space may, for simplicity, be referred to as a diffusion area. However, it will be appreciated that a diffusion area may similarly correspond to a diffusion volume or a geometry comprising other dimensionalities depending on, for instance, the nature of a digital representation. For example, various instances of the embodiments herein may relate to CMOS or FinFET features, which may, in accordance with some embodiments, be characterised by 2D or 3D digital representations. Furthermore, it will be appreciated that a diffusion space may comprise a partial diffusion space. That is, and for example, only, a diffusion space may refer to a portion of diffusion features that may otherwise be physical components, or a portion of a digital representation comprising diffusion features, of an IC, IC layer, or portion thereof.

However, as described above, various transistor configurations are employed in ICs. For example, the diffusion feature 300b comprises three arrays of contact features 310b, 312b, and 314b, wherein contact arrays are separated on the diffusion feature 300b by two polysilicon features 320b and 322b. Based on the configuration of these features, and the inferred connectivity 152 thereof (i.e. based on the overlapping spatial coordinates 146 of the various components), this diffusion area (i.e. the collection of features intersecting the diffusion feature 300b, and optionally a designated region surrounding the diffusion feature 300b and/or features associated therewith), may comprise two transistors in series. That is, and in accordance with various embodiments, the diffusion area comprises, from left to right, a diffusion sub-feature 302b (i.e. a portion of the diffusion feature 300b) having disposed thereon a contact 310b (e.g. a source for a first transistor), followed by a polysilicon feature 320b (e.g. a gate for the first transistor), and then another diffusion sub-feature 304b having disposed thereon another contact 312b (e.g. a drain for the first transistor). In this example, the second transistor of the series may begin from the contact 312b (i.e. the source for the second transistor, which is also the drain of the first transistor), followed by a second polysilicon feature 322b intersecting the diffusion feature 300b (e.g. the gate of the second transistor), and then another contact 314b (e.g. the drain of the second transistor) disposed on the rightmost diffusion sub-feature 306b.

In this example, the diffusion feature 300b is described comprising ‘sub-features’ 302b, 304b, and 306b. However, it will be appreciated that such features may not be physically distinct from one another, or comprise discreet features, although this may be the case, in accordance with some embodiments. However, for the purpose of illustrating various concepts herein disclosed, and in accordance with various embodiments, such sub-features may be referred to as distinct circuit features that are assessed (e.g. iteratively assessed, scanned, or the like), even if such features are components of the same feature in a digital representation, a physical structure of the IC, or the like.

It will further be appreciated that, in accordance with various embodiments, some diffusion area configurations may be bidirectionally read. For example, the description provided above with respect to the diffusion feature 300b related to reading the diffusion area from left to right, wherein the first contact was interpreted to be a source for the first transistor, and so on. However, such diffusion areas may alternatively be read from right to left, wherein the roles of contacts may be reversed, in accordance with some embodiments. For example, the contact 314b, described above as the drain of the second transistor, may be interpreted as the source of a first transistor when the diffusion area is read from right to left. Similarly, the contact 312b, described above as the drain of the first transistor and the source of the second transistor, may, when the diffusion area is read from right to left, be interpreted as the drain of the transistor corresponding to the gate 322b, and as the source of the transistor corresponding to the gate 320b.

As such, contact features, or contacts, may be interpreted as either a source or a drain, or both, in accordance with various embodiments. Indeed, various embodiments herein disclosed need not necessarily identify a particular contact as a global source or drain, but rather may refer to the same contact feature as a source or drain for one transistor, and a source or a drain for another transistor. Accordingly, a contact feature, as described herein, may also be referred to as a ‘channel connection’. Similarly, the term ‘channel connection’ will be understood to refer to a transistor source, a transistor drain, or both, as dictated by the context and/or application at hand.

Further to the notion of ICs and diffusion areas having variable transistor component configurations, FIG. 3 further schematically illustrates the diffusion feature 300c comprising yet another, more complex, transistor component configuration. In this example, the diffusion feature 300c has disposed therein three arrays of contacts 310c, which are generally separated by four polysilicon features 320c. As there is typically one gate per transistor, such a configuration may relate to four transistors in series, despite the fact that there are no contact features directly connected to (i.e. spatially intersecting) the diffusion sub-features 302c and 304c between polysilicon features, as will be further described below.

It will be appreciated that the spatial coordinates of the various features, and in particular an intersection or overlap thereof, may be interpreted as a connectivity for the purposes of transistor component data extraction. Furthermore, it will be appreciated that a particular feature may relate to more than one transistor, and indeed to more than one diffusion area. For example, diffusion areas corresponding to the diffusion features 300d and 300e share a common polysilicon feature 330. In this example, the intersection of the polysilicon feature 330 with diffusion areas 300d and 300e, schematically shown by the overlapping regions 320d and 320e, respectively, may be used to infer a connectivity therebetween. In this example, the polysilicon feature 330 further has disposed thereon a contact feature 332, which is accordingly also shared between respective gates 320d and 320e of respective transistors associated with the diffusion features 300d and 300e, respectively. Similarly, the polysilicon feature 334 of FIG. 3 is shared between diffusion features 300c and 300f.

Accordingly, a polysilicon feature, and indeed other circuit features, may contribute as components to different transistors across different diffusion features. For example, the polysilicon feature 334 serves as a gate in more than one diffusion area, in accordance one embodiment. In yet further embodiments, and as will be further described below, a feature (e.g. a polysilicon feature or a contact feature) may similarly serve as a transistor component for more than one transistor within the same diffusion area.

A corollary to this aspect of interconnectivity extraneous to a diffusion area is that not all features must directly spatially intersect a diffusion feature to be inferred as connected thereto, or connected to features associated therewith, in accordance with various embodiments. For example, and in accordance with various embodiments, one seeking to identify a contact feature associated with a transistor gate corresponding to the diffusion feature 300d of FIG. 3 (or one seeking to assess whether or not there is a contact associated with a particular feature) may infer a connectivity to the contact feature 332 by way of the intersection 320d of the polysilicon feature 330 with the diffusion feature 300d, and, as the polysilicon feature 330 is discrete and continuous, the intersection between the polysilicon feature 330 and the contact feature 332. Similarly, the contact feature 332 may be inferred as the contact associated with the gate of a transistor associated with diffusion feature 300e.

Accordingly, different transistors, even those associated with different diffusion areas, may share a common contact or feature, in accordance with various embodiments. However, it will be appreciated that some embodiments relate to treating (e.g. recording in a netlist) such common features as independent features. For example, a transistor-level or gate-level netlist may have duplicate entries of the contact 332, each entry corresponding to a different transistor. This may be the case whether these transistors are associated with the same diffusion area or feature, or with a different diffusion area or feature.

Returning again to FIG. 1B, non-limiting exemplary transistor extraction preparation steps 150 may further include a division or partitioning of an IC, or an area of interest (AOI) thereof, into tile arrays 154.

FIG. 2B shows one exemplary partitioning 154 of an AOI of an IC into an array of tiles. In this example, the digital representation of filtered diffusion features 204 is partitioned into an array of rectangular tiles (e.g. tiles 220a, 220b, 220c), wherein features 204 are grouped or partitioned into a particular tile based on their spatial position. For example, the tile 220a corresponding to a particular area or volume of the digital representation, which in turn corresponds to a particular area or volume of an IC. Any features corresponding to this area or volume 220a (e.g. diffusion features 204a), are similarly grouped, partitioned, or other identified as corresponding to the tile 220a. Similarly, the diffusion features 204b are partitioned into the tile 220b.

While this example relates to the partitioning of a digital representation of filtered diffusion features 204, it will be appreciated that various embodiments relate to the partitioning of any one or more digital representations of features into tile arrays. For example, and in accordance with various embodiments, digital representations of each of diffusion features, contact features, and polysilicon features may be partitioned into tile arrays, wherein elements of each feature type are grouped into corresponding ‘tiles’ based on their spatial position, or a connectivity to features within a particular tile region. For instance, in the example of FIG. 2B, the tile region 220a may, in accordance with some embodiments, further include any contact and polysilicon features corresponding to the spatial region corresponding to the tile 220a.

As described above, such tile arrays may directly correspond to tiles of a mosaicked image (e.g. pre- or post-mosaicking), or may closely represent such ‘grid’ image tiles of a mosaicked image (e.g. be close in size to SEM image grid tiles, correspond to a similar area as corresponding SEM grid tiles, or the like) in accordance with different embodiments. However, other embodiments relate to the arbitrary partitioning 154 of an AOI of an IC circuit layer, or volume thereof, to tile arrays. In accordance with yet other embodiments, partitioning an IC layer or AOI may be based on, for instance, a density of features in a digital representation. For example, the tile arrays in FIG. 2B may, in accordance with one embodiment, be automatically designated based on clusters of diffusion features.

In accordance with various embodiments, such tile arrays may be processed independently for transistor component data extraction. For instance, a system or method for automatically extracting transistor data may, in accordance with some embodiments, comprise processing array tiles in parallel using respective processing resources, such as processing respective array tiles with respective digital data processors, running multiple threads, a combination thereof, or the like. Further, and in accordance with some embodiments, such parallelisation may comprise one aspect of the generation of tile arrays 154. For example, one embodiment relates to the automatic definition of tile arrays (and corresponding features) in consideration of downstream processing and parallelisation.

Such parallelization need not be limited to parallel assessments of information grouped by association with tiles; rather, the information directly from the feature datasets can be assigned to feature data subsets, each of which can be assessed on respective digital processing resources. Assignment to different feature data subsets can be done arbitrarily or in accordance with a criteria-based selection or a user-designated selection. As a non-limiting example, all feature subsets having connectivity to a particular region or portion of an IC may be assigned to a given digital processing resource. Other criteria for such selections may include, but is not limited to one or more of the following: an association with a diffusion space or a portion thereof or a set thereof; connectivity with certain electrical or spatial features on an IC; connectivity with specific transistors or transistor features. In some embodiments, one or more individual transistors may have some but not all circuit features represented in the given data subset that would be necessary to fully define the transistor; in such cases, circuit features having connectivity to circuit features in other data subsets may be tagged and, when the other data sets have been assessed, the partially defined transistors can then be processed (including in parallel on respective digital processing resources).

In some embodiments, respective digital processing resources can comprise, without limitation, one or more cores of a processor, one or more processors, one or more computers or servers, one or more virtualized computers or computing devices, one or more cloud computing resources, or a combination thereof. As a non-limiting example, Amazon® AWS cloud services can distribute data subsets for a given digital representation of an IC across multiple virtualized storage resources, whereby each data subset can be assessed in parallel using computing resources, virtualize or otherwise, that are associated with each or some of the multiple AWS virtualized storage resources. As such, the time to process even very large and complex feature datasets can be significantly reduced.

In some embodiments, the assessment will proceed in accordance with a spatial relationship; for example, all circuit features from a given diffusion space may be processed sequentially. In other embodiments, circuit features may be assessed using a different or even no or arbitrary relationship; for example, the processing resources may be configured to select data relating to a circuit feature from accessible memory and store the results, and then continue selecting additional circuit features that have not spatial or electrical or other relationship for assessment and storage of results. Such assessment would continue until all or at least some of the transistors on the IC (including specific transistors of interest) have been fully defined.

In embodiments in which the circuit features are assessed directly from the feature dataset, and without reference to the corresponding image and/or not necessarily in accordance with their spatial or connective relationship with other circuit features, processing resources may be configured to select circuit feature data directly from the feature dataset (or data subset as the case may be) and then based on information stored in association therewith, including information relating to feature characteristics and electrical adjacency, define the relationship of the circuit feature, as applicable, within a given transistor and, in some cases, continue until that particular transistor or some or all of the transistors represented in the feature dataset or subset have been fully defined or defined as fully as possible. In some embodiments, the selection from the feature dataset or subset may arbitrary, optimized for memory access, optimized for defining a specific region or regions of interest (including those associated with diffusion regions of interest), or selected based on an association with a given tile or set of tiles.

In some cases, the selection may include association with a specific diffusion region and, notably, need not include all circuit features within a given diffusion space. For example, a given diffusion space may include a plurality of transistors, or it may cover a relatively large portion of the IC; in such cases, it is not necessary to carry out an assessment for all circuit features for a given diffusion region, but rather only a portion of such regions may be assessed. Indeed, in such cases, there may be instances in which not every transistor has a complete set of circuit features listed in a given feature dataset or subset; such information may be stored for later definition upon assessment of the previously unassessed (or independently assessed) portion of the applicable diffusion region.

It will be appreciated that while the tiles in the array of the exemplary embodiment of FIG. 2B comprise between one and sixteen diffusion features (as well as associated contact and polysilicon features), other embodiments relate to tiles comprising many more features. For example, different embodiments relate to the definition of tiles comprising hundreds or thousands of features per tile.

Returning again to FIG. 1B, and in accordance with some embodiments, a pre-processing process 150 may continue with the identification of boundary features in a digital representation (e.g. circuit features that a spatially intersect a boundary of, for instance, an array tile). For example, features 222 of FIG. 2B lie on a boundary of the tile 220c. In contrast, the features 204c of FIG. 2B completely reside within the tile 220c. In embodiments where array tiles are processed independently, features that intersect such a boundary, or features on either side of the boundary but corresponding to the same diffusion area or ‘well’, may present a challenge in downstream processing. Accordingly, some embodiments relate to the identification of boundary features (e.g. features 222) such that they may be processed separately from non-boundary features (e.g. ‘inner’ features 204c).

In accordance with embodiments comprising any one or more of the pre-processing steps of FIG. 1B, such pre-processing may be concluded with the return of processed features 160 for transistor extraction. Such processed features may comprise, for instance, a digital representation of filtered circuit features (e.g. features 204), which may, in some embodiments, be further partitioned into tile arrays. In some embodiments, processed features 160 may comprise non-boundary features (e.g. features 204a, 204b, 204c), while boundary features may be stored elsewhere for separate transistor extraction processes. It will a be appreciated that processed features 160 in a digital representation may comprise different formats, and/or may comprise copies of previous digital representations, or modified versions thereof. For example, one embodiment relates to processed features comprising different arrays of data corresponding to different tile arrays. Another embodiment relates to processed features 160 comprising a list of all features to be processed, with corresponding digital tags or array values indicating to which tile they belong. In accordance with some embodiments, processed features 160 comprise groups or lists in a global array of polygon representations of features. In accordance with some embodiments, such lists may comprise a netlist, a GDSII file, or the like.

Returning again to FIG. 1A, an automatic process for extracting transistor data 100 may then continue using digital representations of circuit features, such as diffusion features 110, contact features 112, and polysilicon features 114. In accordance with some embodiments, such features may relate to processed features 160, as described above. As described above, such digital representations may comprise spatial data associated with each feature, as well as a connectivity (e.g. a list of cross-references) with other features in a dataset. It will be appreciated that such features may be grouped, as described above, in accordance with tile arrays, wherein features in different tiles may be processed separately or independently (e.g. in parallel).

In accordance with various embodiments, circuit features may be processed on a per-diffusion well basis. For example, various embodiments relate to the identification of circuit features (e.g. contacts 112 and polysilicon features 114) that spatially intersect 116 with a diffusion feature 110. Those features that intersect a diffusion feature, as well as a diffusion feature itself, and optionally a surrounding ‘buffer’ area (e.g. an additional area around diffusion well features corresponding to 5%, 20%, or the like, of the corresponding diffusion feature), may be considered as a ‘diffusion area’ 118.

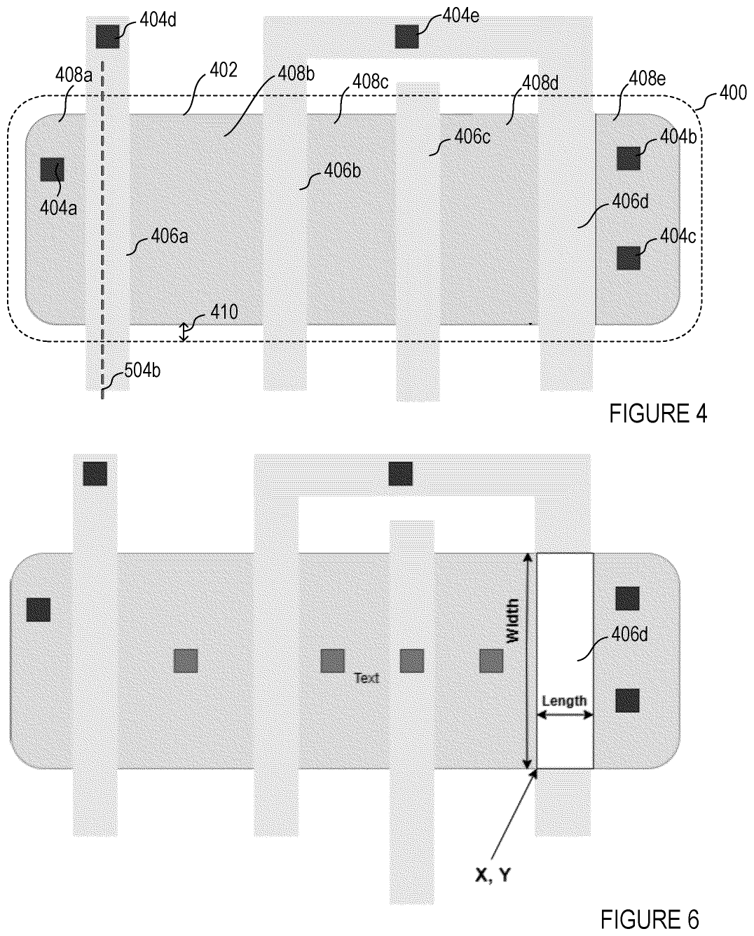

An exemplary diffusion area 400, in accordance with various embodiments, is schematically shown in FIG. 4. In this non-limiting example, the diffusion area 400 comprises features associated with (e.g. spatially intersecting, connected to, or the like) diffusion feature 402. For instance, the diffusion area features (e.g. diffusion area features 118) in this example comprise contact features 404a, 404b, and 404c. In accordance with some embodiments, features that are electrically connected to a diffusion area 400, such as contacts 404d and 404d, may further be considered to be a diffusion area feature 118. However, such external features may, in other embodiments, not be considered as a diffusion area feature 118. However, in accordance with various embodiments, a connectivity of diffusion area features 118, some such external features may be recorded and/or accessed.

The diffusion area features 118 in the diffusion area 400 further comprise polysilicon features 406a, 406b, 406c, and 406d. In accordance with some embodiments, polysilicon features 406b and 406d may be considered to be the same feature, as they are connected outside of the diffusion area 400. An iterative assessment of such a configuration, as will be further described below, may accordingly consider such a feature twice, based on the spatial distribution of the polysilicon feature within the diffusion area. However, other embodiments may consider the polysilicon features 406b and 406d as two separate features within the diffusion area 400. Similarly, while the diffusion feature 402 comprises a discrete feature, various embodiments relate to processing diffusion features as sub-features having different spatial coordinates or distributions. For example, the diffusion feature 402 in FIG. 4 may be processed as different sub-features 408a, 408b, 408c, 408d, and 408e. However, it will be appreciated that other embodiments may relate to processing the diffusion feature 402 as a single feature. In accordance with yet other embodiments, a diffusion feature may be processed as both a discrete, continuous feature and distinct sub-features. For instance, a diffusion feature may be considered as a discrete, continuous feature for the purposes of determining, for instance, a connectivity with other features (e.g. via an overlap of spatial coordinates with polysilicon or contact features); it may then be considered as comprising distinct sub-features for the purposes of, for instance, an iterative assessment of transistor components, as will be further described below, and in accordance with some embodiments.

As described above, a diffusion area may further be characterised by a buffer area or volume around a diffusion feature. For instance, the gap 410 in FIG. 4 between the diffusion feature 402 and the boundary of the diffusion area 400 schematically shows such a buffer region, which may, in accordance with some embodiments, be a function of the size of a diffusion feature 402, the diffusion area 400, or the like. However, different embodiments may relate to, for instance, only diffusion area 400 features. For example, various embodiments relate to iterating over lists of diffusion area features, without necessarily representing them as polygons or images. Such embodiments may therefore not employ a buffer region (e.g. gap 410) around such features.

In accordance with various embodiments, different diffusion areas 118 (e.g. diffusion area 400) may be processed independently for the extraction of transistor component data. It will be appreciated that, similar to the processing of tile arrays described above, such diffusion areas and/or diffusion area features, even within the same tile region (in embodiments comprising tile arrays), may be processed serially or in parallel (e.g. with respective processing resources, multiple threads, different processors, or the like). Further, some embodiments relate to the grouping or partitioning of features into diffusion area feature arrays 118. For example, features corresponding to different diffusion areas 118 may be copied to new respective lists of features, each comprising data related to features of a respective diffusion area. In another embodiment, all features within an array tile, or all features within an AOI may be elements of the same list or array, but tagged therein to be associated with a particular diffusion area or diffusion feature.

In accordance with some embodiments, such lists or arrays may be sorted. For example, features within a diffusion area 118 may be sorted in a list in accordance with a particular spatial coordinate. In one embodiment, this relates to sorting features within a diffusion area 118, or diffusion area array, such that they are listed according to their spatial position in the IC from left to right, right to left, top to bottom, bottom to top, up to down, down to up, or the like. For example, one embodiment relates to sorting diffusion area features based on a left-most coordinate of each feature. However, it will be appreciated that some embodiments do not employ such sorting.

Diffusion area features 118 may then be processed for transistor feature extraction 120. Such feature extraction 120 may comprise, in accordance with some embodiments, incrementally assessing features within each diffusion area 118 by assigning a value (e.g. a state value) to each diffusion area circuit feature based on an identified feature characteristic 122 thereof (e.g. whether the feature is a diffusion feature 110, a contact 112, or a polysilicon feature 114, whether or not the feature is associated with a contact 112, or the like), and a feature characteristic of an electrically adjacent feature 124 in the diffusion area (e.g. whether an electrically adjacent feature is a diffusion feature 110, a contact 112, or a polysilicon feature 114, whether or not the electrically adjacent feature is associated with a contact 112, the electrically adjacent feature is a source, a gate, or a drain, or the like).

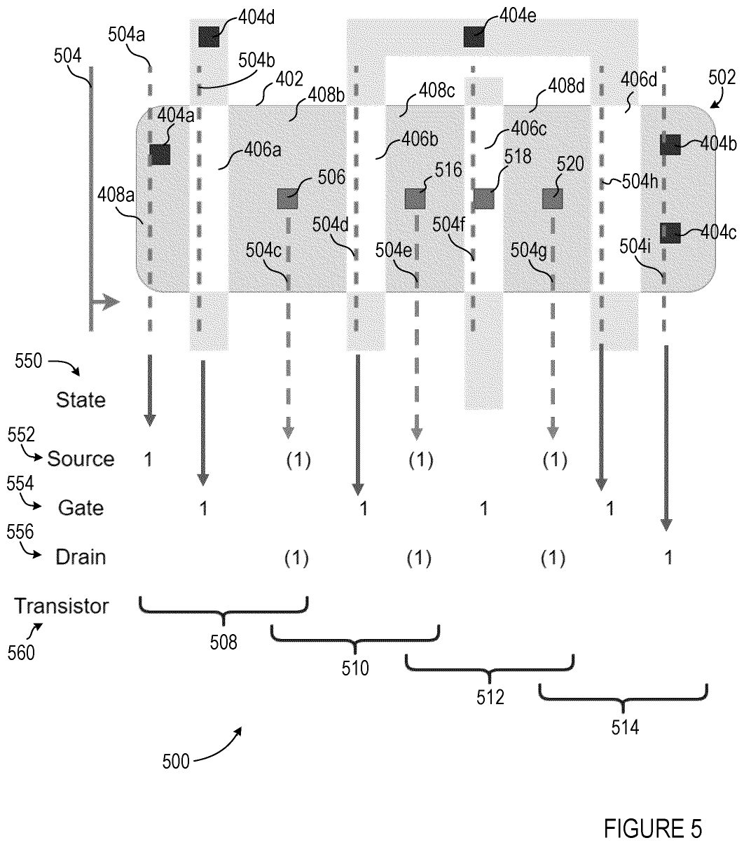

One exemplary feature extraction process 120 is illustrated in FIG. 5. While the exemplary embodiment of FIG. 5 comprises a schematic representation of diffusion area features (those of FIG. 4), and may accordingly correspond to an ‘image-like’ processing (i.e. processing 2D or 3D representations on an image pixel-like basis), various other embodiments relate to processing other digital representations of diffusion area features. For example, and similar to the embodiment of FIG. 5, diffusion area features may be represented by 2D arrays of binary values, wherein each cell or element of the array corresponds to a spatial coordinate of an IC circuit or layer thereof, and wherein a 0 may correspond to the absence of a feature in that area, while a 1 may represent a spatial coordinate that is occupied by a given feature type (e.g. contact, polysilicon, or diffusion feature). Similarly, such a digital array may comprise different values corresponding to a combination of features occupying a particular position (e.g. pixel, voxel, or the like). For example, the absence of any features in a particular voxel may be represented by a 0, while the presence of a diffusion feature, only, may correspond to a 1. The overlap of a diffusion area and a contact may then be indicated by an array value of 2, while the overlap of a diffusion area and a polysilicon feature may comprise a 3. This process may continue for different combinations of features (e.g. polysilicon and contact, polysilicon and contact and diffusion, etc.). In accordance with other embodiments, a diffusion area may comprise a collection of features, only (e.g. as a list or netlist of features). Such lists or arrays, whether sorted or not, may comprise spatial data, and/or one or more characteristics of respective features therein (e.g. a contact, a polysilicon feature, or the like), which may be iteratively assessed, without necessarily being interpreted as a 2D, 3D, or n-D image or like representation. In accordance with various embodiments, inputs to a transistor component extraction process may additionally, or alternatively, comprise collections of polygons representing components of one or more transistors (e.g. a group of transistors in series and/or in parallel).

In FIG. 5, and as described above, an iterative assessment to extract transistor component data 500 from a digital representation of diffusion area features 502 may comprise, in one embodiment, sorting features in accordance with spatial coordinates thereof (e.g. sorting features from left to right, top to bottom, or the like). For example, the diffusion area features 502 of FIG. 5 may be sorted in a digital representation (e.g. polygonal representations, an array of features and/or spatial coordinates or characteristics thereof, or the like), by their left-most spatial coordinate. Such sorting may, in accordance with some embodiments, simplify an iterative assessment (e.g. scanning image-like representations of diffusion area features 502, iterative computations on lists or arrays of diffusion area features 502, or the like). It will be appreciated that various embodiments relate not only to the sorting of diffusion area features 502, but to intersections thereof. For example, the intersection of a diffusion feature and a contact (or, for instance, a polysilicon feature, or a combination thereof) may, in accordance with some embodiments, comprise a diffusion area feature in and unto itself. Such ‘intersecting features’ may accordingly comprise elements that are sorted in such a list, in accordance with some embodiments.

In the exemplary embodiment of FIG. 5, iterative assessment 500 comprises incrementally increasing a ‘scan position’ 504 (or incremental assessment position) which, in this embodiment, is iteratively progressed from left to right (e.g. increasing values of an x coordinate). However, it will be appreciated that various embodiments relate to an iterative assessment that comprises, for instance, iterating through items (e.g. diffusion area features) of a list, or an array of elements. In the embodiment of FIG. 5, however, the assessment position 504 may be incremented in accordance with a designated increment, in accordance with various criteria. For example, the exemplary embodiment of FIG. 5 comprises increasing an assessment position 504 in increments (in the x direction) of one third of the average size of a contact feature in the diffusion area (e.g. an increment step of a number of pixels corresponding to one third of the average contact or polysilicon feature size). Accordingly, a scan position 504 progression may, in such embodiments, assuredly not ‘miss’ or ‘skip’ a feature and/or intersection of features during an iterative assessment 500. However, it will be appreciated that other embodiments may relate to the assessment of features in accordance with different assessment increments, or, for embodiments related to, for instance, the iterative assessment of lists or arrays of circuit features, not even employ a ‘scan position’. Instead, in accordance with such embodiments, an iterative assessment may comprise simply iterating over diffusion area features, or, for ordered or sorted lists or arrays, incrementally assessing the list based on, for instance, spatial coordinates associated with each feature. In accordance with yet other embodiments, such lists or arrays need not even be sorted for an iterative assessment to extract transistor component data. For instance, randomly ordered list items (i.e. diffusion area features) may be iterated over one or more times if, for instance, a property is known or may be inferred about one of the list items (e.g. the left-most feature identified during a first iteration). In accordance with such embodiments, remaining list elements may be identified based a combination of a corresponding characteristic and a characteristic of an electrically adjacent feature.

During the iterative assessment 500, and in accordance with one embodiment, each iteration (e.g. scan position 504, 504a, 504b, 504h, etc., or any position therebetween) may assess whether or not there is an intersection with a diffusion area feature. For instance, each iterative step may comprise a digital logical ‘testing’ step to ascertain if there is an intersection of the scan position with a feature polygon (or an array value, or an equivalent or similar comparison for another form of a digital representation) representing a certain geometry or diffusion area feature. In accordance with some embodiments, an iterative assessment may comprise advancing (e.g. in increasing values of x, and/or in designated increments of a spatial coordinate) an assessment position until such an intersection is identified. For example, in FIG. 5, the assessment position is advanced from left to right (i.e. translated in the positive x direction), beginning at the position 504.

In accordance with some embodiments, an initial assessment position 504 may lie inside of the diffusion feature 402. For instance, it may be understood that a first transistor component of interest identified will be a contact disposed within a diffusion feature (e.g. a transistor source). Accordingly, depending on the application at hand, assessment may begin within the diffusion feature 408a, or at the first contact of a sorted list of diffusion array features. However, in the exemplary embodiment of FIG. 5, the initial assessment position 504 lies outside (i.e. to the left) of the diffusion feature 402. The assessment position in this example is then iteratively progressed rightwards in increments of one third of a contact size, so to ensure that no contacts are missed during iterative assessment, in accordance with various embodiments.

Identification of feature (e.g. a polygon, an element in a list or array of diffusion area features, or the like), in accordance with various embodiments, may depend on a characteristic of the feature intersecting an assessment position (e.g. contact or polysilicon feature), and/or the features intersecting at the scan position (e.g. a diffusion feature with a polysilicon feature, or the like). Further, iterative assessment may identify transistor components based the current state of the assessment process 500.

For example, the embodiment of FIG. 5 further schematically illustrates a finite state machine 550 that is iterated during the assessment process 500. In this example, assessment begins at the position 504, wherein the finite state machine 550 is in a default state (e.g. state=0). Assessment then progresses until an intersection with a first contact 404a is observed at position 504a. Indeed, as various embodiments relate to the identification of sources, gates, and drains for individual transistors, it may be expected that the first observed intersection within the diffusion feature 402 comprises a contact disposed within the diffusion feature 402. Accordingly, and in accordance with various embodiments, the first contact 404a identified may trigger a change in the finite state machine 550, wherein a value is assigned to a source state 552. Accordingly, the first contact 404a may be assigned as a transistor source.

In accordance with some embodiments, the iterative assessment process 500 may continue in, for instance, the designated increment of the scan position. However, other embodiments may relate to logically inferring one or more properties of the system, and assessment may continue from a different position. For example, an in accordance with the embodiment of FIG. 5, the assessment 500 then continues from the rightmost coordinate of the contact 404a, rather than continuing assessment within the contact feature 404a, as the first expected transistor component (a source) has just been defined. Assessment may then continue from the rightmost coordinate of the contact 508 in accordance with the designated assessment increment.

In this example, the assessment position is incremented until the next feature is observed. In this case, the next feature observed is an intersection of a polysilicon feature 406a with the diffusion feature 402, identified at the assessment position 504b. In accordance with some embodiments, the assessment process 500 may, having already identified a source for a first transistor, identify such a polysilicon feature 406a or intersection therewith as a gate for the first transistor. Accordingly, the finite state machine 550 may then assign a gate value 554 to the polysilicon feature 406a.

In some embodiments, the iterative assessment process may continue in iterations related to an arbitrary or a non-arbitrary selection of circuit features from the circuit feature set. For example, circuit features can be assessed in the order of their selection from the overall feature dataset, which may be completely independent of any relationship between incrementally assessed circuit features. In such embodiments, the incremental assessment would continue until all circuit features of interest are assessed, thereby completing the assessment therefor. In related embodiments, that feature dataset may be divided into subsets of circuit features of interest; for example, without limitation, the circuit features may be identified as being all features that share a common and/or pre-identified diffusion area, are located within a circuit region of interest, or share connectivity. Circuit features of interest may be selected in a particular order (or indeed in no order), or according to a particular selection criteria, but otherwise not be incrementally assessed according to any spatial or relational criteria. The selection for each incremental assessment may be based on other operational/computational criteria that is intended to reduce computational resources while assessing all or maximal circuit features. For example, it may be computationally easier to arbitrarily select circuit features from an unordered, or minimally ordered dataset, that are in “nearby” or readily accessible memory (e.g. RAM vs disk). Alternatively, or in combination, performing a search step to assess the “next” circuit feature, may significantly slow down the overall assessment process. Instead, the assessment can be performed, the resulting information for each circuit feature stored, and each transistor and/or diffusion area would be completed in an essentially arbitrary order with much less computational resource impact.

In some embodiments, circuit feature datasets representative of the circuit features can be assessed serially (whether independent of any spatial or connectivity relationship or otherwise) or in parallel. For example, in some embodiments, the circuit feature dataset may be associated with one or more circuit feature data subsets, wherein one or more processing resources are directed to the incremental assessment of each subset. The circuit feature dataset can be divided into any number of data subsets; further, the association into subsets can be in accordance with one or more selection criteria or be arbitrary. As assessment of circuit features in respective subsets progresses, the results can be combined when and if necessary to fully characterize transistors having circuit feature data in two or more subsets. It may be necessary to characterize all circuit features in a given transistor to fully identify and characterize that given transistor. In a cloud computing environment, or indeed any distributed computing environment, a large number of subsets of a dataset can be processed in parallel to increase speed of analysis or decrease reliance on local computing resources. For example, in an Amazon® AWS® environment, a dataset can be associated with many thousands of data subsets, each of which can be processed in parallel with results being combined as analysis thereof progresses (and indeed multiple result sets, and result sets thereof, can be assessed in parallel in like manner).
[ensure that a given diffusion region

In some embodiments, the feature dataset (or subsets thereof) may be pre-processed prior to the iterative process described above; for example, without limitation, circuit features may be labeled as corresponding to, or being the same as, an overlapping circuit feature on adjacent images or image tiles, or as being the same feature or connected to a very large set of connected features in any adjacent image or image tile or as the same as or connected to such feature or features in another subset. For example, a circuit feature dataset may include multiple sets of data that each relate to the same circuit feature as they were originally identified as distinct circuit features simply because they were on adjacent and/or overlapping images or image tiles. In accordance with some embodiments, the assessment process 500 may further assess the gate feature 406a for a contact. In this example, there is no contact within the diffusion area 400. However, and in accordance with some embodiments, the process may identify a contact that is electrically connected to a feature but outside of the diffusion area 400. For instance, the assessment 500 may include identifying an external contact via, for instance, a netlist or other digital representation of the diffusion features, as described above. In this case, the contact 512 was identified as associated with the polysilicon feature 510. In accordance with some embodiments, the contact 512 may therefore be associated as a connection to the gate of the first transistor, and may accordingly be recorded in an output of the assessment (e.g. in a transistor-level or gate-level netlist).

As noted above, the assessment process 500 of FIG. 5 is performed on the diffusion area 400 of FIG. 4. Returning then to FIG. 4, one may observe that, as the assessment position is advanced from the polysilicon feature 406a, the following non-diffusion feature that will be encountered the polysilicon feature 406b. That is, there is no contact in the diffusion area feature 408b. While this may be commonly observed in, for instance, diffusion areas comprising transistors in series, this may present challenges in recording transistor-level or gate-level netlists of IC features, wherein a transistor may preferentially be recorded as having each of a source, a gate, and a drain. However, as there is no contact in the diffusion sub-feature 408b, and a polysilicon feature may be generally understood as a gate feature, the first transistor recorded in, for instance, a netlist, would lack a drain feature. This may, for instance, limit the amount of connectivity that can be established and/or referred to in future processing.

This aspect may further challenge existing technologies or platforms for extracting transistor component data. For instance, while a configuration of a plurality of transistors in series may be common in ICs, a template matching process may perform poorly on such a configuration, as it may require a unique template for each configuration of transistors. The fact that one or more contacts in diffusion area may or may not be present for a given transistor configuration may drastically increase the number of template configurations required for a matching process, thereby decreasing the utility of such a platform.

Thus, various embodiments herein disclosed relate to the generation of a ‘virtual’ node, or a virtual contact feature, in situations where, for instance, a contact is expected, but not observed. Returning again to the embodiment of FIG. 5, this is schematically shown by the virtual contact 506 that is artificially generated during the iterative assessment process 500. In this example, the iterative assessment 500, having progressed from the assessment position 504b, associated with the polysilicon feature 406a, to the position 504d, also associated with a polysilicon feature 406b, identified that consecutive polysilicon features were observed. Accordingly, the iterative assessment 500 generated the artificial or virtual contact 506 in the diffusion sub-feature 408b. Further, as the finite state machine 550 had most recently assigned a gate value to the polysilicon feature 406a, it was inferred that the virtual contact 506 related to a drain state 556, and the finite state machine accordingly assigned a drain value to the virtual contact 506. While various embodiments may relate to the placement of such virtual features in accordance with different processes or logic steps, the virtual contact 506 was placed at the centroid of the diffusion sub-feature 408b, in accordance with one embodiment. Accordingly, the virtual contact 506 was assigned the position 504c during the iterative assessment 500.

As the finite state machine 550 has, upon generation of the virtual contact 506, assigned all three expected transistor components (i.e. a source 404a, gate 406a, and drain 506), a first transistor cycle 508 has been completed. In accordance with some embodiments, transistor component data associated with the transistor cycle 508 may then be recorded in, for instance, a list or netlist of transistors 560. In the embodiment of FIG. 5, however, this process may be repeated the remaining diffusion area features 502 associated with the diffusion area 400.

Accordingly, the iterative assessment 500 may at this point continue, with the finite state machine 550 beginning a second transistor cycle 510 and again seeking a first contact to assign as a source for a second transistor in the diffusion area. In this example, the iterative assessment 500 has established that there is no ‘real’ contact in the diffusion sub-feature 408b. It may therefore, in accordance with some embodiments, assume that the drain of the previous transistor (i.e. virtual contact 506) is the source of a second transistor. Accordingly, the finite state machine 550 may assign a source value 552 to the virtual contact 506 at the assessment position 504c, wherein this second source value now corresponds to the second transistor cycle 510.

The assessment position is again incrementally increased (from left to right, in this example) until the polysilicon feature 406b is identified. The finite state machine 550, having just assigned a source value 552, may then assign a gate value 554 at the position 504d corresponding to the polysilicon feature 406b. Similar to the first transistor cycle 508, the assessment process 500 may then analyse the polysilicon feature 406b for the presence of a contact associated therewith. In this case, the contact 404e, which is detected outside of the diffusion area 400 based on a previously established connectivity, may be passed to the iterative assessment process such that any desired data related thereto may be recorded or analysed.

Iterative assessment 500 may then continue by ‘searching’ for a drain to associate with the second transistor cycle 510. As with the first transistor cycle 508, the following diffusion sub-feature 408c does not comprise a contact. Accordingly, the finite state machine 550 may then assign a drain value 556 to a virtual contact 516 generated at the centroid of the diffusion sub-feature 408c (i.e. position 504e).

At this stage, the embodiment of FIG. 5 has completed a second transistor cycle 510, and may repeat the process of searching for further sources, gates, and drains corresponding to additional transistors in the diffusion area. In this case, a third transistor cycle 512 is initiated, again with the drain of the previous transistor (i.e. virtual contact 516) serving as a source for a third transistor in series. Upon encountering another polysilicon feature 406c, the finite state machine 550 assigns a gate value 554. In this example, however, no contact was found to be associated with the polysilicon feature 406c. Accordingly, a virtual contact 518 is generated at the centroid of the polysilicon feature 406c, the position and/or connectivity of which may be recorded for future reference. Accordingly, such virtual nodes may relate to either a virtual channel connection (i.e. a virtual node associated with a source or a drain), or a virtual gate connection. The third transistor cycle 512 is completed when the finite state machine 550 assigns a drain value 556 to the virtual contact 520 at the centroid of the diffusion sub-feature 408d (i.e. position 504g).

Finally, the iterative assessment 500 of the diffusion area features 502 is completed when the finite state machine assigns source, gate, and drain values for a fourth transistor cycle 514. In this case, the source of the fourth transistor cycle 514 is assigned to the virtual contact 520 at the assessment position 504g, the gate is assigned to the polysilicon feature 406d at the position 504h (which is associated with the contact 404e), and the drain is assigned to one or both of the real contacts 404b or 404c at the assessment position 504i.

It will be appreciated that, at any stage of an iterative assessment, the assessment position may automatically be re-positioned or re-assigned to the next feature or intersection, or other position of interest. For example, and without limitation, an assessment position may ‘skip’ to the next intersection of diffusion area features 502 upon assigning a state value 550. In accordance with one embodiment, this may comprise, upon the identification of a gate feature, skipping the assessment position to the next polysilicon-diffusion feature boundary to begin searching for a contact feature (e.g. a drain).

Similarly, for iterative assessments over diffusion area features of a list or array thereof, a state value may be assigned to a current item based on, for instance, a current finite state machine value (e.g. source and gate identified for a given transistor cycle), before iteratively repeating this process for subsequent items in the list. In accordance with such embodiments, virtual features may be generated as elements of the list or array. For example, based on a characteristic of a current feature of a list (e.g. a polysilicon feature), a characteristic of an electrically adjacent feature (e.g. the previous feature of the list is also a polysilicon feature), and/or a finite state machine value (e.g. a transistor cycle has identified a source and a gate), a virtual contact may be generated as one (or two) elements of the list as a drain for one transistor cycle (and a source for another transistor cycle), in accordance with one embodiment. In accordance with yet another embodiment, an iterative assessment may comprise the generation of contacts when there is absent a right- or left-most contact in diffusion area. For example, if the contacts 404a, and/or 404b and 404c were not already present in a digital representation of diffusion area features 502 of FIG. 5, then one or more virtual contacts may be generated for to establish, for instance, a source(s) and/or drain(s) for corresponding transistors. In such embodiments, the coordinates of such virtual features may be generated in accordance with a centroid or other coordinate of an associated feature (e.g. diffusion sub-features 408a and/or 408e).

In accordance with various embodiments, an iterative assessment may make one or more logical assumptions. Such assumptions may, in accordance with some embodiments, be coded for as digital instructions, or may be implemented by an operator. For example, an automatic extraction of transistor components may assume that there are as many transistors in a diffusion area as there are distinct polysilicon features. In accordance with some embodiments, such distinct polysilicon features may correspond to a globally discrete feature, but may appear more than once in a diffusion area as, for instance, multiple transistor gates (e.g. gates 406b and 406d of FIG. 5. Accordingly, an iterative assessment may, for instance, generate contacts such that all pins of a transistor (i.e. source, gate, and drain) are identified for a number of transistor cycles that equals the number of polysilicon features of a diffusion area. Additionally, or alternatively, an iterative assessment may conclude upon an increasing assessment position corresponding to a furthest boundary of a diffusion feature in a diffusion area, in accordance with some embodiments. In accordance with yet another embodiment, an iterative assessment process may relate to the automatic assumption and/or recording of a nature of transistor connections in a diffusion area. For example, adjacent gates in a diffusion area (e.g. gates separated by a single virtual or real contact and intersecting the same diffusion feature) may be assumed to be transistors in series.

It will further be appreciated that various data and/or data types may be recorded as extracted transistor data, in accordance with various embodiments. For example, the transistor components (i.e. sources, gates, and drains) of FIG. 5 were described with respect to the solid or dashed lines corresponding to assessment positions 504 and 504a to 504i. These positions are described for illustrative purposes, in accordance with one embodiment. In accordance with other embodiments, features may be characterised by, for instance, other positional or like information. For example, FIG. 6 is a schematic illustrating potential spatial data that may be recorded for a transistor component automatically extracted from a digital representation of a diffusion area of an IC. In this example, a transistor gate (i.e. the gate corresponding to the polysilicon feature 406d in the diffusion feature area 400) is characterised by the x, y coordinates of the bottom-left coordinate of the identified rectangular gate, as well as the length and width thereof. Such data may be extracted and recorded for all identified transistor components (e.g. sources, gates, and drains) for all identified transistors, and recorded in various formats. For example, such component data, as well as transistor IDs, types, associated metal layers, connectivity with other components, or the like, may be recorded as, for instance, a netlist, in JSON of GDSII format, or the like. It will be appreciated that while the exemplary embodiment of FIG. 6 comprises two-dimensional spatial data related to an IC feature, various other embodiments relate to the extraction of 3D or great-dimensional data with respect to diffusion area features. For instance, a digital representation may comprise depth-related data of transistor components or other IC layer features, which may be similarly processed in accordance with an iterative assessment.

Such recording may be performed, in accordance with various embodiments, at different stages of component extraction. For example, one embodiment relates to recording transistor and/or component data as each transistor cycle (e.g. cycle 508, 510, 512, or 514) is completed, upon completion of assessment of a diffusion area (e.g. extraction of all transistor components from the diffusion area 400), upon analysis of all diffusion areas of an array tile (e.g. tile 220b), or the like. Further, it will be appreciated that extracted component data may be added to, for instance, local transistor data lists (e.g. netlists corresponding to a diffusion area, tile region, area of interest, or the like), to a global transistor list (e.g. all transistors extracted for an IC or layer thereof), a combination thereof, or the like. Furthermore, it will be appreciated that various embodiments relate to performing such iterative assessments for any one or more layers of an IC, such as, but not limited to, various functional layers of an IC, various metal layers of an IC, or the like.

It will further be appreciated that while the description above related to the extraction of transistor components from “non-boundary” diffusion areas (i.e. those not intersecting a tile array boundary, the boundary of an AOI, or the like), boundary transistors may be processed independently and added to an appropriate list or netlist of transistors and/or transistor components (e.g. a global transistor- or gate-level netlist), in accordance with various embodiments.

In accordance with yet other embodiments, iterative assessment (e.g. iterative assessment 500) may be performed in accordance with various coordinate systems. For example, while the assessment position 504 is iteratively increased from left to right in FIG. 5, other embodiments relate to iteratively assessing a diffusion area from top to bottom or bottom to top (e.g. in the y direction), or in accordance with an arbitrary axis. For example, images of an IC may comprise diffusion areas substantially aligned with an arbitrary axis (e.g. circuit features are substantially aligned parallel or perpendicular to an axis that is 27 degrees from ‘horizontal’, as recorded as a digital representation). Various embodiments may accordingly relate to iterative assessment in accordance with such an access, and/or in a designated increment with respect to that axis.

While the present disclosure describes various embodiments for illustrative purposes, such description is not intended to be limited to such embodiments. On the contrary, the applicant's teachings described and illustrated herein encompass various alternatives, modifications, and equivalents, without departing from the embodiments, the general scope of which is defined in the appended claims. Except to the extent necessary or inherent in the processes themselves, no particular order to steps or stages of methods or processes described in this disclosure is intended or implied. In many cases the order of process steps may be varied without changing the purpose, effect, or import of the methods described.

Information as herein shown and described in detail is fully capable of attaining the above-described object of the present disclosure, the presently preferred embodiment of the present disclosure, and is, thus, representative of the subject matter which is broadly contemplated by the present disclosure. The scope of the present disclosure fully encompasses other embodiments which may become apparent to those skilled in the art, and is to be limited, accordingly, by nothing other than the appended claims, wherein any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims. Moreover, no requirement exists for a system or method to address each and every problem sought to be resolved by the present disclosure, for such to be encompassed by the present claims. Furthermore, no element, component, or method step in the present disclosure is intended to be dedicated to the public regardless of whether the element, component, or method step is explicitly recited in the claims. However, that various changes and modifications in form, material, work-piece, and fabrication material detail may be made, without departing from the spirit and scope of the present disclosure, as set forth in the appended claims, as may be apparent to those of ordinary skill in the art, are also encompassed by the disclosure.

What is claimed is:

1. A method for automatically extracting transistor data from a digital representation of at least a portion of an integrated circuit (IC), said digital representation comprising a feature dataset comprising at least one list of circuit features of the IC and, corresponding thereto, at least one of spatial coordinates thereof and connectivity to other circuit features, the method automatically executed by at least one digital data processor operable to execute digital instructions for:
defining at least one diffusion space corresponding to respective spatial regions of the IC each comprising at least a portion of a diffusion feature;
incrementally assessing diffusion space circuit features of the feature dataset that intersect with the at least one diffusion feature or portion thereof, by assigning a current state value to each diffusion space circuit feature based on an identified current feature characteristic associated therewith and an identified feature characteristic of an electrically adjacent feature in the corresponding diffusion space.

2. The method of claim 1, wherein a given diffusion space is limited to a portion of the respective spatial region comprising the diffusion space circuit features necessary to define at least one individual transistor.

3. The method of either one of claim 1 or claim 2, wherein said incrementally assessing diffusion space circuit features comprises incrementally assessing said diffusion space circuit features in accordance with a selection from said feature dataset and using information in said feature dataset to identify feature characteristics and electrical adjacency.

4. The method of any one of claims 1 to 3, wherein said incrementally assessing diffusion space circuit features comprises incrementally assessing said diffusion space circuit features in accordance with a designated spatial increment.

5. The method of any one of claims 1 to 4, further comprising:
partitioning the feature dataset into said diffusion space circuit features for each of said at least one discrete diffusion space.

6. The method of any one of claims 1 to 5, wherein said incrementally assessing diffusion space circuit features comprises iterating a finite state machine for said assigning a current state value.

7. The method of any one of claims 1 to 6, wherein said respective spatial region of the IC comprises a three-dimensional volume of the IC.

8. The method of any one of claims 1 to 7, wherein the digital representation is derived from one or more images of the IC.

9. The method of any one of claims 1 to 8, wherein the digital representation comprises one or more of pixel data, binary data, pixel data, polygon data, image data, greyscale image data, or image data.

10. The method of any one of claims 1 to 9, wherein the digital representation is representative of one or more of a scanning electron microscopy (SEM) image, or a transmission electron microscopy (TEM) image.

11. The method of any one of claims 1 to 10, wherein the digital representation is representative of a mosaicked image generated from a plurality tiled images acquired with a high magnification imager.

12. The method of any one of claims 1 to 11, wherein the list of circuit features corresponds to one or more of a gate dataset, a polysilicon dataset, a contact dataset, a metal dataset, or a diffusion space dataset.

13. The method of any one of claims 1 to 12, wherein the method is repeated for a plurality of IC layers of the IC.

14. The method of any one of claims 1 to 13, further comprising generating a netlist based at least in part on said current state value assigned for each of said diffusion space circuit features.

15. The method of any one of claims 1 to 14, wherein the spatial coordinates of the circuit features relate to a spatial distribution of the circuit features.

16. The method of claim 15, wherein said spatial distribution corresponds to one or more of a respective characteristic position, a width, or a height of respective surface features.

17. The method of any one of claims 1 to 16, wherein a respective digital processing resource assesses information relating to one of: each of the discrete diffusion spaces; each of a plurality of given selections from said feature data; or each of a subset of discrete diffusion spaces.

18. The method of any one of claims 1 to 17, further comprising:
partitioning the digital representation into a plurality of tile regions corresponding to respective spatial regions of the IC;
wherein said at least one discrete diffusion space comprising at least one discrete diffusion feature is defined for each of said plurality of tile regions.

19. The method of claim 18, wherein said partitioning the digital representation is automatically performed based on a distribution of circuit features.

20. The method of either one of claim 18 or claim 19, further comprising:
distinguishing, based at least in part on the spatial coordinates of the circuit features, between boundary circuit features and inner circuit features, wherein boundary circuit features comprise circuit features intersecting a boundary of at least one of said plurality of tile regions.

21. The method of claim 20, wherein:
said at least one discrete diffusion feature comprises an inner circuit feature.

22. The method of any one of claims 18 to 21, wherein said defining at least one diffusion space and said incrementally assessing diffusion space circuit features for at least two of said plurality of tile regions are digitally executed in parallel by respective digital processing resources.

23. The method of any one of claims 1 to 18, further comprising:
partitioning the digital representation into a plurality of feature data subsets corresponding to selections of diffusion space circuit features from the list of circuit features;
wherein the diffusion space circuit features for at least one individual transistor are defined for at least one of said feature data subsets.

24. The system of claim 23, wherein said defining at least one diffusion space and said incrementally assessing diffusion space circuit features for at least two of said feature data subsets are digitally executed in parallel by respective digital processing resources.

25. The method of any one of claims 1 to 24, wherein said assigning a current state value comprises assigning a value of corresponding to a transistor channel connection or a transistor gate.

26. The method of claim 25, wherein said transistor channel connection comprises a transistor source or a transistor drain or a transistor contact.

27. The method of any one of claims 1 to 26, wherein said assigning a current state value comprises assigning a virtual channel connection to a current diffusion space circuit feature based at least in part on an absence of a contact feature associated with said current diffusion space feature.

28. A non-transitory computer-readable medium comprising digital instructions to be implemented by one or more digital data processors to automatically extract transistor data from a digital representation of at least a portion of an integrated circuit (IC), said digital representation comprising a feature dataset comprising at least one list of circuit features of the IC and, corresponding thereto, at least one of spatial coordinates thereof and connectivity to other circuit features, by:
defining at least one diffusion space corresponding to respective spatial regions of the IC each comprising at least a portion of a diffusion feature;
incrementally assessing diffusion space circuit features of the feature dataset that intersect with the at least one diffusion feature or portion thereof by assigning a current state value to each diffusion space circuit feature based on an identified current feature characteristic associated therewith and an identified feature characteristic of an electrically adjacent feature in the corresponding diffusion space.

29. The non-transitory computer-readable medium of claim 28, wherein a given diffusion space is limited to a portion of the respective spatial region comprising all of the diffusion space circuit features necessary to define at least one individual transistor.

30. The non-transitory computer-readable medium of either one of claim 28 or claim 29, wherein said incrementally assessing diffusion space circuit features comprises incrementally assessing said diffusion space circuit features in accordance with a selection from said feature dataset and using information in said feature dataset to identify feature characteristics and electrical adjacency.

31. The non-transitory computer-readable medium of any one of claim 28 to claim 30, wherein said incrementally assessing diffusion space circuit features comprises incrementally assessing said diffusion space circuit features in accordance with a designated spatial increment.

32. The non-transitory computer-readable medium of any one of claims 28 to 31, further comprising digital instructions for:
partitioning the feature dataset into said diffusion space circuit features for each of said at least one discrete diffusion space.

33. The non-transitory computer-readable medium of any one of claims 28 to 32, wherein said incrementally assessing diffusion space circuit features comprises iterating a finite state machine for said assigning a current state value.

34. The non-transitory computer-readable medium of any one of claims 28 to 33, wherein said respective spatial region of the IC comprises a three-dimensional volume of the IC.

35. The non-transitory computer-readable medium of any one of claims 28 to 34, wherein the digital representation is derived from one or more images of the IC.

36. The non-transitory computer-readable medium of any one of claims 28 to 35, wherein the digital representation comprises one or more of pixel data, binary data, pixel data, polygon data, image data, greyscale image data, or image data.

37. The non-transitory computer-readable medium of any one of claims 28 to 36, wherein the digital representation is representative of one or more of a scanning electron microscopy (SEM) image, or a transmission electron microscopy (TEM) image.

38. The non-transitory computer-readable medium of any one of claims 28 to 37, wherein the digital representation is representative of a mosaicked image generated from a plurality tiled images acquired with a high magnification imager.

39. The non-transitory computer-readable medium of any one of claims 28 to 38, wherein the list of circuit features corresponds to one or more of a gate dataset, a polysilicon dataset, a contact dataset, a metal dataset, or a diffusion space dataset.

40. The non-transitory computer-readable medium of any one of claims 28 to 39, wherein the digital instructions are repeatedly executable for a plurality of IC layers of the IC.

41. The non-transitory computer-readable medium of any one of claims 28 to 40, wherein the digital instructions are further executable to generate a netlist based at least in part on said current state value assigned for each of said diffusion space circuit features.

42. The non-transitory computer-readable medium of any one of claims 28 to 41, wherein the spatial coordinates of the circuit features relate to a spatial distribution of the circuit features.

43. The non-transitory computer-readable medium of claim 42, wherein said spatial distribution corresponds to one or more of a respective characteristic position, a width, or a height of respective surface features.

44. The non-transitory computer-readable medium of any one of claims 28 to 43, wherein a respective digital data processor assesses information relating to one of: each of the discrete diffusion spaces; each of a plurality of given selections from said feature data; or each of a subset of discrete diffusion spaces.

45. The non-transitory computer-readable medium of any one of claims 28 to 44, further comprising digital instructions for:
partitioning the digital representation into a plurality of tile regions corresponding to respective spatial regions of the IC;
wherein said at least one discrete diffusion space comprising at least one discrete diffusion feature is defined for each of said plurality of tile regions.

46. The non-transitory computer-readable medium of claim 45, wherein said partitioning the digital representation is automatically performed based on a distribution of circuit features.

47. The non-transitory computer-readable medium of either one of claim 45 or claim 46, further comprising digital instructions for:
distinguishing, based at least in part on the spatial coordinates of the circuit features, between boundary circuit features and inner circuit features, wherein boundary circuit features comprise circuit features intersecting a boundary of at least one of said plurality of tile regions.

48. The non-transitory computer-readable medium of claim 47, wherein:
said at least one discrete diffusion feature comprises an inner circuit feature.

49. The non-transitory computer-readable medium of any one of claims 45 to 48, wherein said defining at least one diffusion space and said incrementally assessing diffusion space circuit features for at least two of said plurality of tile regions are digitally executed in parallel by respective digital processing resources.

50. The method of any one of claims 28 to 44, wherein said digital instructions further comprise instructions for:
partitioning the digital representation into a plurality of feature data subsets corresponding to selections of diffusion space circuit features from the list of circuit features;
wherein the diffusion space circuit features for at least one individual transistor are defined for at least one of said feature data subsets.

51. The system of claim 50, wherein said defining at least one diffusion space and said incrementally assessing diffusion space circuit features for at least two of said feature data subsets are digitally executed in parallel by respective digital processing resources.

52. The non-transitory computer-readable medium of any one of claims 28 to 51, wherein said assigning a current state value comprises assigning a value of corresponding to a transistor channel connection or a transistor gate.

53. The non-transitory computer-readable medium of claim 52, wherein said transistor channel connection comprises a transistor source or a transistor drain or a transistor contact.

54. The non-transitory computer-readable medium of any one of claims 28 to 53, wherein said assigning a current state value comprises assigning a virtual channel connection to a current diffusion space circuit feature based at least in part on an absence of a contact feature associated with said current diffusion space feature.

55. A system for automatically extracting transistor data from a digital representation of at least a portion of an integrated circuit (IC), said digital representation comprising a feature dataset comprising at least one list of circuit features of the IC and, corresponding thereto, at least one of spatial coordinates thereof and connectivity to other circuit features, the system comprising:
a digital data storage device having stored thereon the digital representation;
at least one digital data processor operable to execute digital instructions for:
receiving as input the digital representation;
defining from the digital representation at least one diffusion space corresponding to respective spatial regions of the IC each comprising at least a portion of a diffusion feature;
incrementally assessing diffusion space circuit features of the feature dataset that intersect with the at least one diffusion feature or portion thereof by assigning a current state value to each diffusion space circuit feature based on an identified current feature characteristic associated therewith and an identified feature characteristic of an electrically adjacent feature in the corresponding diffusion space.

56. The system of claim 55, wherein a given diffusion space is limited to a portion of the respective spatial region comprising all of the diffusion space circuit features necessary to define at least one individual transistor.

57. The system of either one of claim 55 or claim 56, wherein said incrementally assessing diffusion space circuit features comprises incrementally assessing said diffusion space circuit features in accordance with a selection from said feature dataset and using information in said feature dataset to identify feature characteristics and electrical adjacency.

58. The system of any one of claims 55 to 57, further comprising a high magnification imager operable to acquire an image of the IC, and wherein the digital representation of the IC is representative of said image.

59. The system of claim 58, wherein said high magnification imager comprises an electron microscope.

60. The system of any one of claims 55 to 59, wherein a respective digital processing resource assesses information relating to one of: each of the discrete diffusion spaces; each of a plurality of given selections from said feature data; or each of a subset of discrete diffusion spaces.

61. The system of any one of claims 55 to 60, wherein said digital instructions further comprise instructions for:
partitioning the digital representation into a plurality of tile regions corresponding to respective spatial regions of the IC;
wherein said at least one discrete diffusion space comprising at least one discrete diffusion feature is defined for each of said plurality of tile regions.

62. The system of claim 61, wherein said defining at least one diffusion space and said incrementally assessing diffusion space circuit features for at least two of said plurality of tile regions are digitally executed in parallel by respective digital processing resources.

63. The system of any one of claims 55 to 60, wherein said digital instructions further comprise instructions for:
partitioning the digital representation into a plurality of feature data subsets corresponding to selections of diffusion space circuit features from the list of circuit features;
wherein the diffusion space circuit features for at least one individual transistor are defined for at least one of said feature data subsets.

64. The system of claim 63, wherein said defining at least one diffusion space and said incrementally assessing diffusion space circuit features for at least two of said plurality of feature data subsets are digitally executed in parallel by respective digital processing resources.
